(19) United States
(12) Patent Application Publication
(10) Pub. No.: US 2025/0098393 A1
(43) Pub. Date: Mar. 20, 2025

(54) MONOLITHIC INTEGRATION OF VERTICAL ELECTROCHEMICAL TRANSISTORS

(71) Applicant: Northwestern University, Evanston, IL (US)

(72) Inventors: Antonio F. Facchetti, Chicago, IL (US); Tobin Jay Marks, Evanston, IL (US); Jaehyun Kim, Evanston, IL (US)

(21) Appl. No.: 18/888,580

(22) Filed: Sep. 18, 2024

Related U.S. Application Data
(60) Provisional application No. 63/539,146, filed on Sep. 19, 2023.

(51) Int. Cl. H10K 10/46; H10K 19/00; H10K 19/10; H10K 85/10

(52) U.S. Cl. CPC H10K 10/478; H10K 10/488; H10K 10/491; H10K 19/10; H10K 19/201; H10K 85/113; H10K 85/1135

(57) ABSTRACT

Vertical organic electrochemical transistors (vOECTs), high-density arrays of the vOECTs, and complementary circuits that incorporate the vOECTs are provided. Also provided are methods of making the vOECTs via micropatterning of redox-active organic semiconductor films by direct electron-beam (e-beam) exposure. In the fabrication methods, highly energetic electrons convert exposed areas of an organic semiconductor into an electronic insulator that retains ionic conductivity, while unexposed areas of the organic semiconductor remain redox-active. This vOECT fabrication approach results in topological continuity between the electrically insulating areas and the redox-active areas of the organic film, which facilitates monolithic integration.

### CROSS REFERENCE TO RELATED APPLICATIONS

The present application claims priority to U.S. provisional patent application No. 63/539,146 that was filed Sep. 19, 2023, the entire contents of which are incorporated herein by reference.

### REFERENCE TO GOVERNMENT RIGHTS

This invention was made with government support under grant number 70-NANB19H005 awarded by the National Institute of Standards and Technology, and grant number DMR1720139 awarded by the National Science Foundation, and grant number FA9550-22-1-0423-P00001 awarded by the Air Force Office of Scientific Research and grant number N00014-20-1-2116-P00004 awarded by the Office of Naval Research. The government has certain rights in the invention.

### BACKGROUND

Organic electrochemical transistors (OECTs) and other organic semiconductor-based electronic components have been explored for applications in emerging wearable electronics, biosensors, and neuromorphic devices due to their unique properties such as low driving voltage, excellent amplification and sensing properties, great structural versatility as well as potential for high-throughput production. These characteristics are attractive for multiplexed signal processing requiring high-density monolithic integration. Recently, the development of conventional OECTs (cOECTs), having a co-planar source-drain electrode architecture, has advanced transconductance (gₘ) and switching speed metrics. However, with few exceptions, cOECTs have limited temporal and/or operational stability, slow redox processes and poorly balanced p-(hole-transporting)/n-(electron-transporting) OECT performance, limiting implementation in advanced signal processing for bioelectronics and multiplexed state-of-the-art electronics. (Spyropoulos, G. D. et al., Sci. Adv. 5, eaau7378 (2020); Wu, X. et al. Adv. Funct. Mater. 33, 2209354 (2023); Cea, C. et al. Nat. Mater. 19, 679-686 (2020); Khodagholy, D. et al. Nat. Commun. 4, 2133 (2013); Schmatz, B. et al., Adv. Funct. Mater. 29, 1905266 (2019); Jiang, C. et al., APL Mater. 8, 091102 (2020).) Moreover, this architecture exhibits constrained geometric fill-factor for high-resolution and compact complementary circuits. To address some of these issues, vertically stacked OECT architectures (vertical OECT, vOECT) have been developed. (Abarkan, M. et al. Adv. Sci. 9, 2105211 (2022); Koutsouras, D. A. et al., Adv. Electron. Mater. 9, 2200868 (2023); Kleemann, H. et al., Adv. Funct. Mater. 30, 1907113 (2020); Huang, W. et al. Nature 613, 496-502 (2023).) However, scalable patterning methods for the semiconductor materials and optimization of the architectural topology for efficient monolithic integration remain technologically challenging, yet necessary, for achieving complex, high-density OECT arrays/circuits for multi-functional data analysis.

Epitaxial silicon-based and inorganic semiconductors have successfully relied on photolithography to shrink transistor channel length and pattern all circuit materials; however, this technique is non-optimal for organic semiconductors due to their limited chemical orthogonality with photoresists and typical severe contamination of the channel material. Equally important, conventional photolithography of the semiconductor will not address topological irregularities preventing vOECT integration into active-matrix circuits. Thus, alternative micro/nanofabrication strategies for patterning organic semiconductors for vOECT are required for integration as well as to suppress parasitic/off-currents, reduce cross talk between neighboring devices, and minimize power consumption in high-resolution OECT circuit arrays.

### SUMMARY

Mechanically flexible vOECTs and high-density arrays and circuits, including complementary inverters, that incorporate the vOECTs are provided. Also provided are facile and high-throughput methods of making the vOECTs via micropatterning of organic semiconductor materials by electron-beam (e-beam) exposure.

In the fabrication methods, highly energetic electrons are used to convert exposed areas of an ionically conducting organic semiconductor into an electrical insulator that retains ionic conductivity, while the unexposed areas of the organic semiconductor retain their redox-active semiconducting character. This vOECT fabrication approach results in topological continuity between the electrically insulating areas and the redox-active areas, which facilitates monolithic integration. P-type and n-type vOECT active-matrix arrays made using the fabrication methods are characterized by high transconductance, fast transient times, and stable switching cycles. By way of illustration, p-type and n-type vOECT active-matrix arrays having a transconductance in the range from 0.05 to 2 S, transient times of less than 100 μs, and performance stability over 100,000 or more switching cycles can be fabricated.

One embodiment of a method of fabricating a vertical organic electrochemical transistor in an ionically conducting organic semiconductor film includes the steps of: forming a first electrode on a substrate; forming an organic film comprising an ionically conducting conjugated organic semiconductor over the first electrode; exposing an area of the organic film to an electron-beam, the exposed area surrounding an unexposed area of the organic film, whereby the ionically conducting organic semiconductor in the exposed area of the organic film is converted into an ionically conducting electrical insulator by the deconjugation of the ionically conducting conjugated organic semiconductor; forming a second electrode over the unexposed area of the organic film; placing an electrolyte in contact with the organic film; and placing a gate electrode in contact with the electrolyte.

One embodiment of vertical organic electrochemical transistor includes: a first electrode; a second electrode; an organic film between the first electrode and the second electrode, an electrolyte in contact with the organic film; and a gate in contact with the electrolyte. The organic film comprises an ionically conducting semiconductor channel region embedded in an ionically conducting electrically insulating out-of-channel region, wherein the ionically conducting semiconductor channel region forms a semiconductor channel between the first electrode and the second electrode. The ionically conducting semiconductor channel region comprises a conjugated organic semiconductor and the ionically conducting electrically insulating out-of-channel region comprises the same organic semiconductor in a partially or fully deconjugated form.

One embodiment of a vertically stacked complementary inverter includes: a first electrode; a second electrode; a first organic film between the first electrode and the second electrode, a third electrode; a second organic film between the second electrode and the third electrode, an electrolyte in contact with the first organic film and the second organic film; and a gate in contact with the electrolyte. In the first organic film an ionically conducting semiconductor channel region is embedded in an ionically conducting electrically insulating out-of-channel region, wherein the ionically conducting semiconductor channel region forms a semiconductor channel between the first electrode and the second electrode. The ionically conducting semiconductor channel region of the first organic film comprises an n-type conjugated organic semiconductor and the ionically conducting electrically insulating out-of-channel region of the first organic film comprises the n-type organic semiconductor in a partially or fully deconjugated form. Similarly, in the second organic film an ionically conducting semiconductor channel region is embedded in an ionically conducting electrically insulating out-of-channel region, wherein the ionically conducting semiconductor channel region forms a semiconductor channel between the second electrode and the third electrode. The ionically conducting semiconductor channel region of the second organic film comprises a p-type conjugated organic semiconductor and the ionically conducting electrically insulating out-of-channel region of the second organic film comprises the p-type organic semiconductor in a partially or fully deconjugated form

Other principal features and advantages of the invention will become apparent to those skilled in the art upon review of the following drawings, the detailed description, and the appended claims.

### BRIEF DESCRIPTION OF THE DRAWINGS

Illustrative embodiments of the invention will hereafter be described with reference to the accompanying drawings, wherein like numerals denote like elements.

FIGS. 1A-1I. Fabrication and monolithic integration of vOECTs based on e-beam patterning. FIG. 1A shows a cross-sectional illustration of the vOECT architecture used in the Example demonstrating a topologically continuous organic semiconductor (OSC) film through in-channel active and out-of-channel inactive regions. FIG. 1B shows a vOECT fabrication process: (i) formation of a bottom source electrode on a substrate; (ii) application of an OSC over the bottom electrode and substrate; (iii) direct OSC patterning to form (iv) active (e-beam unexposed) and inactive (e-beam exposed) regions in the OSC film; (v) formation of a top drain electrode over the e-beam exposed area of the OSC; (vi) application of an electrolyte over the top electrode and contacting a gate electrode with the electrolyte. FIG. 1C shows an illustration of a vOECT array. FIG. 1D shows chemical structures of the p-/n-type OSC polymers, bgDPP-g2T and bHOMO-gDPP, respectively, and the cross-linkable polymer Cin-Cell. Note, the OSC film is composed by a 9:2 weight blend of bgDPP-g2T or bHOMO-gDPP and Cin-Cell to enhance the functional stability of the device. FIG. 1E shows surface height profile along the cutline of a bgDPP-g2T film. FIG. 1F-1I shows transfer characteristics of bgDPP-g2T (FIG. 1F) and bHOMO-gDPP (FIG. 1H) vOECTs before and after OSC patterning with a dose of 300 μC/cm². Dependence of the gₘ and I_{on/off} on the e-beam dose for bgDPP-g2T (FIG. 1G) and bHOMO-gDPP (FIG. 1I) vOECTs.

FIGS. 2A-2J. vOECT ionic and electronic transport characterization and transient response stability. FIGS. 2A, 2C show vertical impedance spectra of p- (FIG. 2A) and n-type (FIG. 2C) OSCs at direct current (FIGS. 2D, 2C) bias of 0.5V and −0.7V respectively. FIGS. 2B, 2D show lateral impedance spectra of p- (FIG. 2B) and n-type (FIG. 2D) OSCs at 0.0V d.c bias. The insets in FIGS. 2A and 2B are the vertical and conventional (lateral) EIS testing configurations, respectively. In FIG. 2B, 300* represents data collected where excess electrolyte was removed from the OSC. All data were collected in 0.1 M NaCl (aq) with a 0.02 V alternating current (a.c.) oscillation amplitude. FIGS. 2E, 2F show transient response of bgDPP-g2T I and bHOMO-gDPP (FIG. 2F) vOECTs. For the p-type bgDPP-g2T vOECTs, V_{G} is switching between 0 V and −0.5 V with V_{D}=−0.5 V, and for the n-type bHOMO-gDPP vOECTs, V_{G} is switching between 0 V and +0.7 V with V_{D}=+0.5 V. FIGS. 2G, 2H show dependence of transient time on channel dimensions for bgDPP-g2T (FIG. 2G) and bHOMO-gDPP (FIG. 2H) vOECTs. FIGS. 2I, 2J show cycling stability (frequency of 10 Hz) of bgDPP-g2T (FIG. 2I) and bHOMO-gDPP (FIG. 2J) vOECTs. In all devices W=d=10 μm, L˜100 nm, dose=300 μC/cm².

FIGS. 3A-3H. Characterization of e-beam unexposed and exposed OSC films. FIGS. 3A, 3B show out-of-plane one-dimensional line-cuts for GIWAXS patterns of bgDPP-g2T (FIG. 3A) and bHOMO-gDPP (FIG. 3B) films under different e-beam doses. FIGS. 3C, 3D show FTIR spectra of bgDPP-g2T (FIG. 3C) and bHOMO-gDPP (FIG. 3D) films under different e-beam doses. FIGS. 3E-3H show deconvoluted XPS spectra of bgDPP-g2T films in the spectral regions of C1s and S2p before (FIGS. 3E, 3F) and after (FIGS. 3G, 3H) e-beam exposure (dose=300 μC/cm²).

FIGS. 4A-4H. High-density monolithically integrated vOECT arrays fabricated by e-beam exposure. FIG. 4A shows a transconductance map of the wafer-scale vOECTs; the spots indicate the measured devices. FIG. 4B shows transfer characteristics of 100 bgDPP-g2T vOECTs (W=d=10 μm). FIGS. 4C, 4D show low (FIG. 4C) and high (FIG. 4D) magnification optical microscopy images, and a CPOM image (FIG. 4E) of a bgDPP-g2T vOECT array. FIG. 4F shows a circuit schematic of 10×10 vOECT active-matrix arrays (DL=drain line, SL=source line). FIG. 4G shows transconductance distribution in the 10×10 bgDPP-g2T vOECT arrays. FIG. 4H shows statistical distribution histograms of transconductance (left) and threshold voltage (right) for 100 devices, which are all functioning.

FIGS. 5A-5F. 2D areal mapping and flexible vOECT arrays. FIGS. 5A, 5B show a schematic illustration (FIG. 5A) and an optical microscope image (FIG. 5B) of 16×16 vOECT active-matrix arrays. FIGS. 5C, 5D show a transconductance profile of 16×16 vOECT arrays before (FIG. 5C) and after (FIG. 5D) semiconductor channel patterning via e-beam exposure. FIG. 5E shows change of transconductance and threshold voltage during in-situ bending tests of a flexible bgDPP-g2T vOECT array as a function of bending radius. FIG. 5F shows change of transconductance and threshold voltage of bgDPP-g2T vOECTs under mechanical strain (bent at 0.5 mm radius) during 1000 cycles. In all devices W=d=10 μm, L˜100 nm, dose=300 μC/cm².

FIGS. 6A-6K. High-resolution vertically stacked complementary circuits. FIGS. 6A, 6B show a schematic illustration (FIG. 6A) and optical microscope image (FIG. 6B) of a 10×10 VSCI array based on p- and n-vOECTs. FIG. 6C shows a representative voltage output characteristic of a VSCI along with the voltage gain. FIG. 6D shows voltage gain distribution in a 10×10 VSCI array. Note, for VSCI array measurements, PBS electrolyte was applied with Ag/AgCl gate electrode. FIGS. 6E, 6F show illustration (FIG. 6E) and output characteristics (FIG. 6F) of a NAND logic circuit. Inset: Optical image of the NAND. FIGS. 6G, 6H show illustration (FIG. 6G) and output characteristics (FIG. 6H) of a NOR logic circuit. Inset: Optical image of the NOR. FIGS. 6I, 6J show cross-sectional illustration of NAND (FIG. 6I) and NOR (FIG. 6J). FIG. 6K shows switching stability of VSCI logic circuits. In all devices W=d=10 μm and L˜100 nm.

FIGS. 7A-7B. vOECT architectures with different OSC patterning methodologies. FIG. 7A shows a schematic illustration of a vOECT with the OSC patterned by e-beam exposure and thus enabling the enlargement of the ion-penetration region. FIG. 7B shows a schematic illustration of a vOECTs (previous work of Huang, W. et al., Nature 613, 496-502 (2023)) with the OSC patterned by a photocrosslinking/development process. In this architecture the drain electrode blocks one half of the area potentially accessible to the electrolyte.

FIGS. 8A-8B. Electrochemical Impedance Spectroscopy. Vertical (FIG. 8A) and lateral (FIG. 8B) EIS testing configurations with the corresponding equivalent circuits, where Rₛ is the system resistance, Q_{dl} is the constant phase element corresponding to the double layer capacitance behavior at the electrode surface, R_{ct} is the charge transfer resistance, Rᵢ is the ionic resistance, and Rₑ is the electronic resistance.

FIGS. 9A-9B. Electrical characterization of vOECTs with different channel dimensions. Dependence of the on-current and transconductance on the channel dimensions for bgDPP-g2T (FIG. 9A) and bHOMO-gDPP (FIG. 9B) vOECTs.

FIGS. 10A-10B. vOECT stability characteristics. Transient response of bgDPP-g2T (FIG. 10A) and bHOMO-gDPP (FIG. 10B) vOECTs with the indicated W and d values. For the p-type bgDPP-g2T vOECTs, V_{G} is switching between 0 V and −0.5 V with V_{D}=−0.5 V, and for the n-type bHOMO-gDPP vOECTs, V_{G} is switching between 0 V and +0.7 V with V_{D}=+0.5 V.

FIGS. 11A-11B. 2D-GIWAXS measurements. FIGS. 11A-11B show in-plane one-dimensional line-cuts, based on GIWAX measurements, for bgDPP-g2T and bHOMO-gDPP blend films exposed at different e-beam doses.

FIGS. 12A-12B. UV-vis-NIR spectroscopic characterization. Absorption spectra of bgDPP-g2T (FIG. 12A) and bHOMO-gDPP (FIG. 12B) films exposed at different e-beam doses.

FIGS. 13A-13B. Schematic representation of conventional etch-based patterned and e-beam exposure patterned VSCI arrays. FIG. 13A shows an illustration of a VSCI array fabrication via conventional patterning/etching of the organic semiconductor. In this case, top and bottom electrodes are in electrical contact along the whole metal line preventing addressed each OECT. FIG. 13B shows an illustration of VSCI array fabrication via e-beam exposure patterning of the organic semiconductor. With this methodology, the e-beam exposed region of the organic semiconductor is inactive (insulator), thus the top and bottom contact lines are electrically insulated.

FIGS. 14A-14B. Fabrication process for the vertically stacked complementary circuits. FIG. 14A shows the following for the NAND: i) Ground electrode deposition; ii) N-type semiconductor coating; iii) N-type semiconductor patterning; iv) Node electrode deposition; v) N-type semiconductor coating; vi) N-type semiconductor patterning; vii) Output electrode (V_{OUT}) deposition; viii) P-type semiconductor coating; ix) P-type semiconductor patterning; x) V_{DD} and side-gate electrode deposition; xi) PEDOT:PSS fabrication on top of the side-gate; xii) Ion-gel fabrication. FIG. 14B shows the following for the NOR: i) Ground electrode deposition; ii) N-type semiconductor coating; iii) N-type semiconductor patterning; iv) Output electrode (V_{OUT}) deposition; v) P-type semiconductor coating; vi) P-type semiconductor patterning; vii) Node electrode deposition; viii) P-type semiconductor coating; ix) P-type semiconductor patterning; x) V_{DD} and side-gate electrode deposition; xi) PEDOT:PSS fabrication on top of the side-gate; xii) Ion-gel fabrication.

FIGS. 15A-15H. Electrical characteristics of vOECT without/with a PEDOT:PSS layer on the gate electrode. FIG. 15A shows a cross-section illustration of a solid-state ion-gel-based vOECT without PEDOT:PSS on the side-gate. FIGS. 15B-15D show corresponding transfer characteristics (FIG. 15B), output characteristics (FIG. 15C), and transconductance (FIG. 15D). FIG. 15E shows a cross-section illustration of a solid-state ion-gel-based vOECT with PEDOT:PSS on the side-gate. FIGS. 15F-15H show corresponding transfer characteristics (FIG. 15F), output characteristics (FIG. 15G), and transconductance (FIG. 15H). W=d=10 μm.

### DETAILED DESCRIPTION

High-performance vOECTs for monolithically integrated complementary logic circuits are provided. The vOECTs are fabricated using spatially selective e-beam exposure of an organic semiconductor film for the direct and high-resolution patterning of a transistor channel in said film with excellent uniformity, high yield, and scalable pattern formation. Because organic semiconductor films lend themselves to implementation in simple and scalable vertical device architectures, both p-channel and n-channel vOECTs can be fabricated with ultra-high-performance characteristics, enabling their use in high-performance complementary circuits. The vOECTs and circuits made therefrom have applications in the fields of biological systems, neuromorphic electronics, stretchable/wearable electronics, and other fields where large-area and complex bioelectronic devices are used.

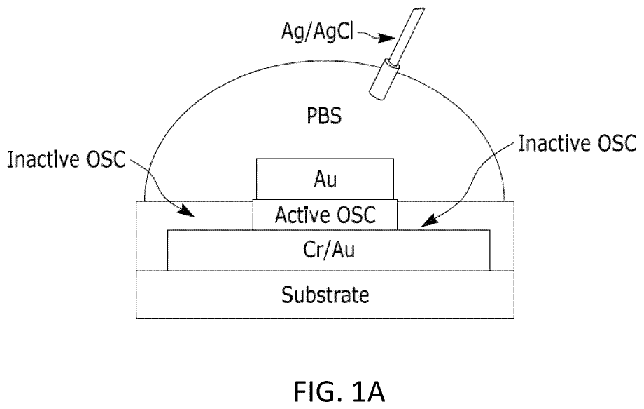

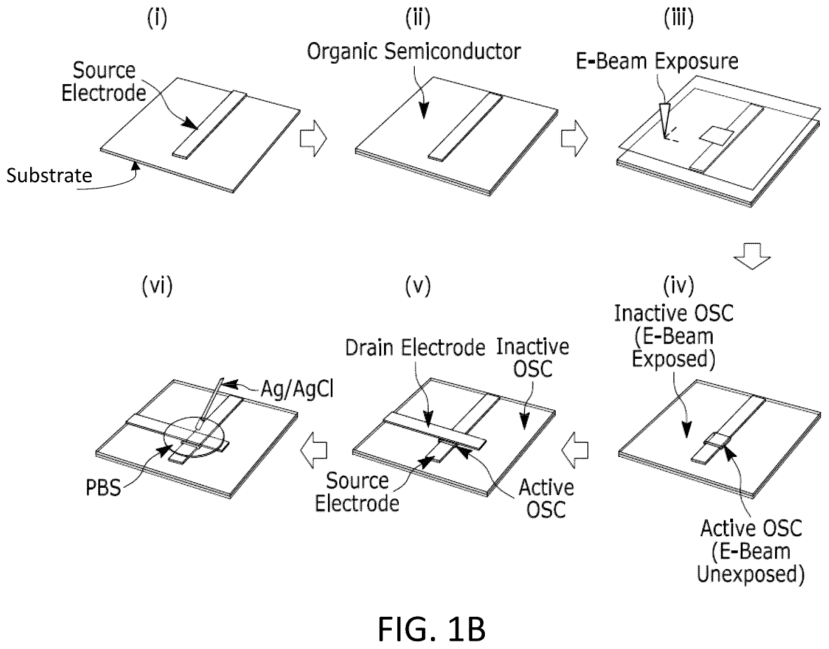

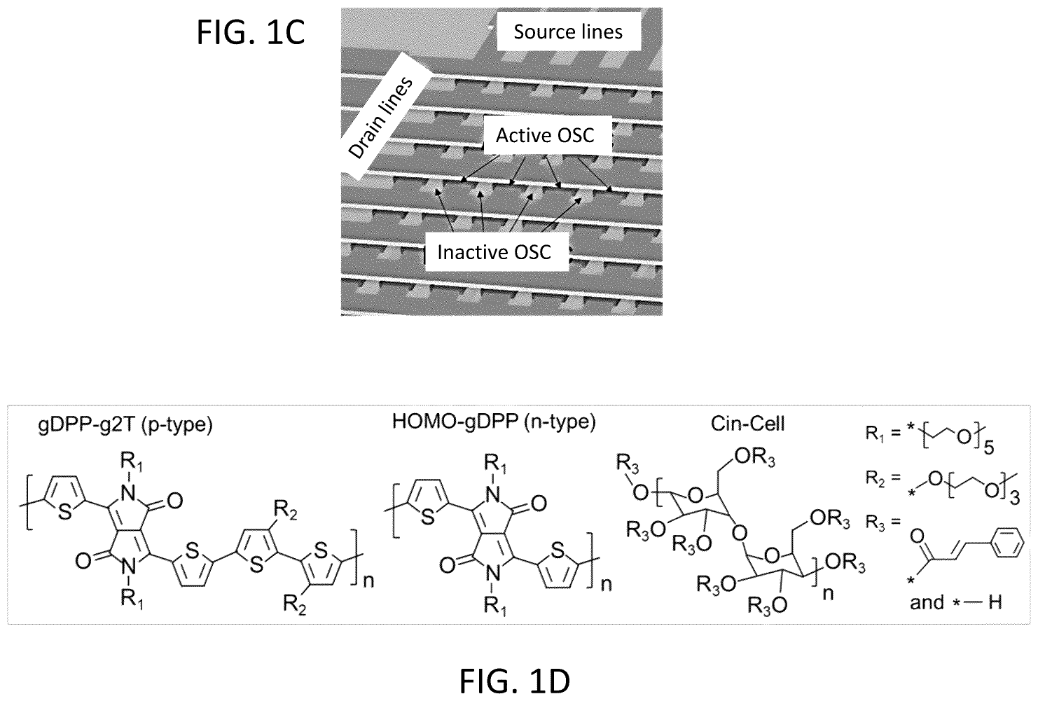

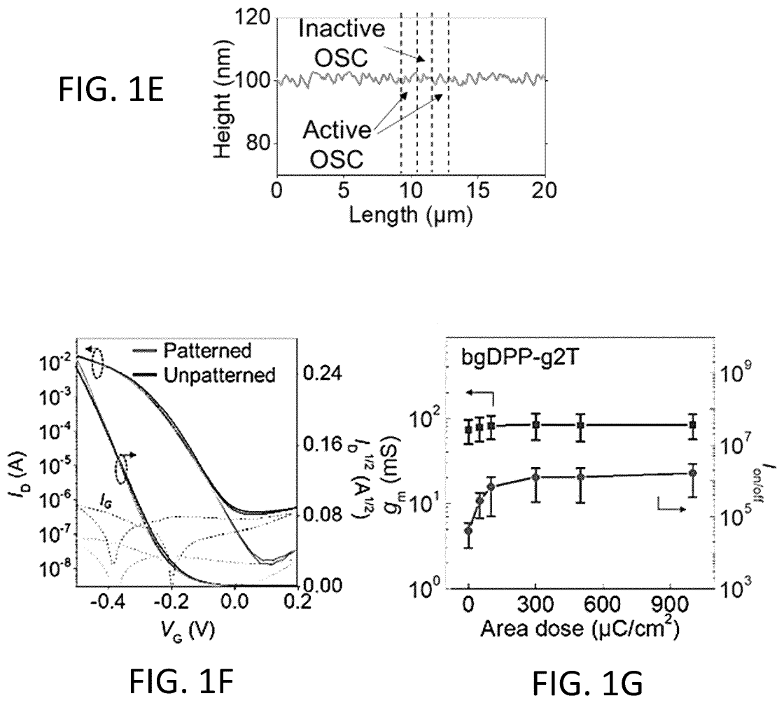

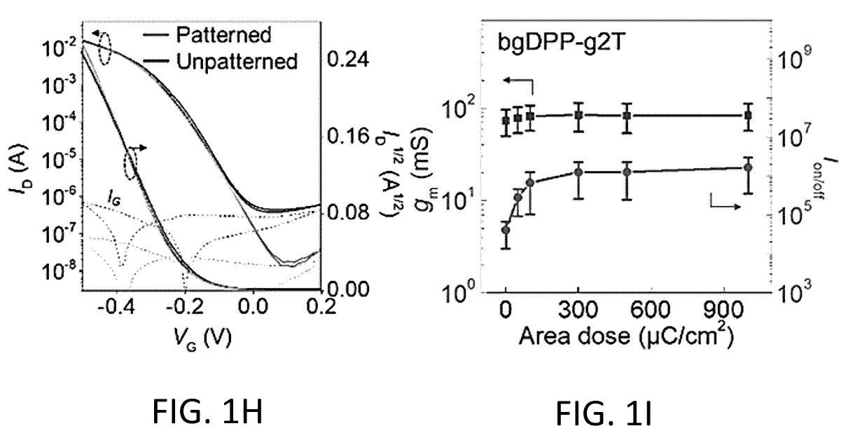

The structure of a vOECT is shown schematically in FIG. 1A. The vOECT includes: a substrate; a first (bottom) Cr/Au electrode; a topologically continuous OSC film comprising an in-channel active (Active OCS) and out-of-channel inactive (Inactive OSC) regions; a second (top) Au electrode disposed over the in-channel active region; a PBS electrolyte in electrical communication with the OSC film; and an Ag/AgCl gate electrode in electrical communication with the electrolyte. The in-channel active region of the OSC film provides an ionic ally conducting semiconductor channel between the source and the drain. It should be noted that, while particular electrode materials and a PBS electrode are shown in FIG. 1A and FIG. 1B, these are for illustrative purposes only. Other, electrode materials and electrolytes can be used.

The organic semiconductor of the semiconducting channel is redox-active, having mixed electronic and ionic transport that allows redox doping and de-doping in the electrolyte. A variety of p-type and n-type redox-active organic semiconductors can be used to make the vOECTs. The organic semiconductor may be a conjugated organic polymer semiconductor or a conjugated small organic molecule semiconductor.

Redox-active conjugated organic polymer semiconductors are conjugated organic polymers having carrier-conducting backbones that can donate and/or accept electrons. The redox-active semiconducting organic polymers may be homopolymers or copolymers having side-chain substituents for enabling processability from solution. Depending upon the type of polymer, the backbone may be electron-conducting (n-type), hole-conducting (p-type), or may conduct both electrons and holes (ambipolar charge transport). Homopolymers and copolymers of diketopyrrolopyrrole (DPP), isoindigo (IID), dithienothiophene (DTT), benzodithiophene (BDT), naphthalene diimide (NDI), perylene diimide (PDI), thieno[3,4-c]pyrrole-4,6-dione (TPD), bithiophene imide (BTI), benzothiadiazole (BT), indocenodithiophene (IDTT), (2,2-((2Z,2Z)-((12,13-bis(2-ethylhexyl)-3,9-diundecyl-12,13-dihydro-[1,2,5]thiadiazolo[3,4-e]thieno[2,″3:4′,5′]thieno[2′,3′:4,5]pyrrolo[3,2-g]thieno[2′,3′:4,5]thieno[3,2-b]indole-2,10-diyl)bis(methanylylidene))bis(5,6-difluoro-3-oxo-2,3-dihydro-1H-indene-2,1-diylidene))dimalononitrile) (Y6), and/or quinoxaline (Qx) monomers are examples of redox-active conjugated organic polymer semiconductors. Other examples include poly(3,4-ethylenedioxythiophene) polystyrene sulfonate (PEDOT:PSS), and poly(benzimidazobenzophenanthroline) (BBL). DPP copolymers include copolymers of DPP and thiophene, bithiophene, and/or dithienovinylene (TVT). The DPP polymers may have ethylene glycol side-chains or other hydrophobic or hydrophilic side-chains.

In some embodiments of the vOECTs, the organic semiconductor is a conjugated small molecule, which can be processed by physical vapor deposition or solution processing. Examples of small molecules include acenes, perylenes, oligothiophene, oligoarenes, phthalocyanines, and heteroacenes. These may optionally be functionalized with electron withdrawing (e.g., C═O, COOR, COOH, CN, F, and/or Cl), electron-donating (e.g., OH, OR, O(CH₂CH₂)OR, and/or NR₂, where R represents H or alkyl groups), and/or alkyl groups.

Optionally, photocurable organic molecules may be blended with the organic semiconductors to render the resulting blends photoprocessable. For the purposes of this disclosure, an organic molecule is photocurable if it can absorb radiation and undergo radiation-induced crosslinking reactions with other organic molecules to form covalent bonds. The photocurable organic molecules may be monomers, dimers, higher order oligomers, and/or polymers that are functionalized with one or more radiation-absorbing substituents. For example, photocurable organic molecules functionalized with ultraviolet (UV) wavelength-absorbing groups, such as cinnamate, dienecinnamate, cumarine, vinyl, allyl, acrylate, azide, and/or oxetane groups may use used for photocuring using UV radiation (e.g., wavelengths in the range from about 10 nm to about 400 nm). When the photocurable organic molecules are exposed to radiation that is absorbed by said molecules, covalent crosslinks are formed between the photocurable organic molecules to produce a crosslinked polymer network that enhances the structural integrity of the organic film. This crosslinked polymer network may blend with the OSC in a single-phase or may be partially of fully phase-separated. To avoid interference with the operation of the vOECTs, the photocurable organic molecules and the crosslinked polymers formed therefrom are desirably non-redox-active.

In some examples of the blends, the photocurable organic molecules are carbohydrates that are functionalized with UV absorbing functional groups. However, other types of organic molecules, including polyesters, can also be used. The use of carbohydrates and polyesters is advantageous because they are soluble in environmentally friendly solvents and, therefore, can be photopatterned using those environmentally friendly solvents. The photocurable carbohydrates include cinnamate-functionalized cellulose, glucose, and/or sucrose, examples of which are described in Wang, Zhi, et al. “Cinnamate-Functionalized Natural Carbohydrates as Photopatternable Gate Dielectrics for Organic Transistors.” Chemistry of Materials 31.18 (2019): 7608-7617.

Known methods can be used for forming films of the organic semiconductors on a substrate, including solution-phase processes such as spin-coating, slot coating, printing (e.g., inkjet printing, screen printing, pad printing, offset printing, gravure printing, flexographic printing, lithographic printing, mass-printing and the like), spray coating, electrospray coating, drop casting, dip coating, and blade coating. By way of illustration, PCT publication WO 2023/114560 describes methods for the synthesis of redox-active p- and n-type organic semiconductors and blends of such semiconductors with photocurable organic molecules, and methods of forming films of said redox-active semiconductors and blends. The substrate can be composed of an inorganic material, such as a metal oxide or metalloid oxide (e.g., SiO₂) or an organic material, such as an organic polymer.

Once the redox-active organic semiconductor film is formed, the area of the film outside of the intended vOECT channel areas (the “out-of-channel” area) is irradiated using an e-beam having an energy sufficient to deconjugate the backbone of the semiconductor polymer. As a result of the irradiation, charge transport in the irradiated portion of the semiconductor film is disrupted by deconjugation of the semiconducting polymer and disruption of crystalline order within the film, which converts the polymer material in the e-beam-irradiated area into an electrically insulating, but still ionically conducting, material. Within the patterned organic semiconductor film, the electrically insulating area transitions into the unexposed areas (the channel regions) that retain their semiconducting character, thereby enabling active-matrix pixilation in a manner that cannot be achieved using conventional etch-patterned methodologies. The retention of ionic conductivity in the out-of-channel area is advantageous because it allows for ions to enter the channel of the vOECT through the entire perimeter defined by the vOECT electrodes, as illustrated in the Example.

The organic semiconductor in the out-of-channel region need not be fully deconjugated; it is sufficient that the organic semiconductor be deconjugated to a sufficient extent to render it electrically insulating, such that electric current does not pass through the out-of-channel region when the vOECT is in operation. Thus, it is sufficient for the conjugation in the organic semiconductor to be reduced by, for example, at least 50%, at least 60%, at least 70%, at least 90%, or at least 95%. The extent of deconjugation that will render a given conjugated semiconductor electrically insulating will depend on the particular organic semiconductor being used.

Advantages of using direct e-beam patterning to define channels in the organic semiconductor film include: the option of eliminating the use of masks or resist/developing solvent/stripping; enabling ultra-small vOECTs to be fabricated with well-defined/patterned electronically-active (semiconducting) channel regions; and efficient multi-layer integration due to the presence of a planarized, topologically smooth, and continuous organic semiconductor film composed of one or more electronically-active channel regions embedded in an electronically-inactive (electrically insulating) out-of-channel region. The channels that are patterned in the OSC films can have very small dimension. By way of illustration, the vOECTs can have a channel length, corresponding to the OSC film thickness, of 150 nm or less, including channel lengths in the range from 50 nm to 100 nm and channel areas (W×d), corresponding to the overlap between the top and bottom electrodes, of 20 μm×20 μm or smaller, including channel areas in the range from 5 μm×5 μm to 10 μm×10 μm. However, channel dimensions outside of these ranges can also be used.

While some embodiments of the fabrication methods described herein are carried out without the use of masks or resist/developing solvent/stripping, the organic semiconductor may be patterned using electromagnetic or particle radiation (e.g., ultraviolet, UVC, or plasma) to deactivate the charge transport in the organic semiconductor to define the out-of-channel semiconducting channel regions in a mask-based lithography process.

A method for fabricating a vOECT is shown schematically in FIG. 1B. In the methods, the components of the vOECTs, including the source and the drain can be formed using known techniques, as illustrated in the Example. In a typical process, an electrically conducting material (e.g., a metal, conducting polymer, such as PEDOT:PSS, or an electrically conducing oxide) is deposited on a substrate using, for example, thermal evaporation, sputtering, or photolithographic patterning, to provide a bottom source electrode (FIG. 1B, panel (i)); a film of the redox-active organic semiconductor is formed over the source electrode using, for example, spin-coating (FIG. 1B, panel (ii)); the out-of-channel region is then defined in the organic semiconductor film via direct e-beam patterning (FIG. 1B, panels (iii) and (iv); a top drain electrode is formed over an unexposed (i.e., channel) region of the organic semiconductor film using, for example, thermal evaporation and patterning of an electrically conductive material (e.g., a metal, conducting polymer, such as PEDOT:PSS, or an electrically conducting oxide) (FIG. 1B, panel (v)); an electrolyte, such as a phosphate buffer solution (PBS) or a salt solution (e.g., NaCl or KPF₆ solutions), is then applied over the drain electrode and the organic film (FIG. 1B, panel (vi)); and a gate electrode (e.g., a metal, such as Ag/AgCl or conducting polymer, such as PEDOT:PSS) is placed in contact with the electrolyte (FIG. 1B, panel (vi)). The electrolyte, may be, but need not be an organic electrolyte and may be a liquid (e.g., a solution of ions dissolved in a solvent or a solvent mixture, such as a saline solution—e.g., a NaCl solution or phosphate-buffered saline (PBS)), a gel (e.g., 1-ethyl-3-methylimidazolium ethyl-sulfate ([C2MIM][EtSO₄]), 1-butyl-3-methylimidazolium bis(trifluoromethylsulfonyl)imide ([BMIM][TFSI]), or 1-ethyl-3-methylimidazoliumbis(trifluoromethylsulfonyl)imide ([EMIM][TFSI])), or a solid (e.g., thermoplastic polyurethane or a photopatternable solid electrolyte based on the ionic liquid [EMIM][EtSO₄] in a polymer matrix). (While the bottom electrode in the vOECT of FIG. 1B is designated as a source and the top electrode is designated as a drain, it is also possible for the bottom electrode to serve as the drain and the top electrode to serve as the source.)

One or more vOECTs can be integrated into the patterned organic semiconductor film using the one or more ionically conducting semiconductor channel regions defined within the film as the transistor channels. Arrays of vOECTs can be fabricated by using direct patterning of the OSC film to form multiple isolated channels and forming a vOECT for each of the channels. FIG. 1C shows an illustration of a vOECT array.

In a vOECT, current flowing between the source and drain electrodes is modulated by the application of a bias voltage applied to the gate electrode. The electrostatic repulsion caused by the application of this gate voltage induces ions from the electrolyte to diffuse into the ionically conducting semiconductor channel region of the organic semiconductor and change the oxidation state of the redox-active semiconducting organic polymer. Depending upon whether the redox-active semiconducting organic polymer is n-type doped (n-channel) or p-type doped (p-channel) and the mode of operation of the transistor (depletion or accumulation), the charge carries may either decrease or increase the drain current. Due to the full or partial deconjugation of the organic semiconductor in the out-of-channel regions, electric current does not flow through those region.

Complementary circuits can be formed by incorporating a vOECT having a given channel type (n-channel or p-channel) with a second vOECT having a complementary (i.e., opposite) channel type (p-channel or n-channel) in a circuit. In the complementary circuits, one or both OECTs may be a vOECT. Examples of complementary circuits that can be fabricated include vertically stacked complementary inverters, complementary logic circuits, such as NAND gates, ring oscillators, and differential pairs. By way of illustration, vertically stacked complementary inverters (VSCIs) are circuits in which an n-type vOECT sits directly on top of p-type vOECT, or vice versa. Such 3D geometry enables much higher integration density as it requires a smaller footprint per inverter, relative to OECTs having a planar construction.

### Example

This Example demonstrates the monolithic integration of high-density p- and n-type vOECT active-matrix arrays, as well as their complementary logic circuits, realized via direct electron-beam exposure of both p- and n-channel organic semiconductor (OSC) films, respectively.

Semiconductor Patterning by e-Beam Exposure and vOECT Performance

The schematic representation and fabrication of a single vOECT and a monolithically integrated vOECT array are shown in FIGS. 1A-1C (for details see Methods). As OSC channel materials, blends were employed consisting of a redox-active polymer (gDPP-g2T for the p-type OECTs and HOMO-gDPP for the n-type OECTs) with a redox-inert cinnamate-cellulose polymer (Cin-Cell) in an optimal weight ratio of 9:2 (FIG. 1D). Note, unless specifically indicated, all experiments were carried out using blends of OSC+Cin-Cell, which are referred to hereafter as bgDPP-g2T and bHOMO-gDPP. The OSC films were deposited by spin-coating the corresponding blend solution onto an Au source electrode (or Au parallel line electrodes for the array) which is (are) patterned by conventional photolithography. Next, the area outside the channel region(s) was e-beam irradiated (up to 1000 μC/cm²), which is an energy exceeding those of typical C—C (3.63 eV), C—H (4.25 eV), C═C (6.34 eV), and C═O (7.59 eV) bonds. Thus, e-beam exposure can disrupt charge transport in the exposed region by the combination of several mechanisms including chemical bond cleavage, new bond formation, and disruption of crystalline order (vide infra). A second perpendicularly arranged Au drain electrode (Au lines) was (were) thermally evaporated and patterned by photolithography resulting in devices with a channel length (L) corresponding to the OSC film thickness (˜100 nm) and a channel area (W×d) given by the overlap between the two Au lines (in most of the experiments, 10 μm×10 μm). Cross-polarized optical microscopy (CPOM) images during/after vOECT fabrication indicated that upon e-beam irradiation the semiconductor film loses typical strong birefringence characteristic of the semicrystalline morphology. Note, the e-beam exposure also allows sub-micrometer patterning of both bgDPP-g2T and bHOMO-gDPP as shown in CPOM images. The device (array) was completed by dispensing a PBS electrolyte solution and using an Ag/AgCl gate electrode. Note, achieving patterned electronically-active islands surrounded by an electronically-inactive areas, which are continuous and non-relief as shown in the linecut of FIG. 1E, is key to the system-level circuit integration (vide infra).

Representative transfer characteristics and electrical performances of unpatterned/e-beam patterned bgDPP-g2T and bHOMO-gDPP vOECTs are shown in FIGS. 1F-1I. The data in FIGS. 1F-1H were taken at an e-beam dose of 300 μC/cm². Data were also collected at other doses. All performance parameters are provided in Table 1. These data demonstrate excellent switching behavior for both p- and n-type patterned devices, achieving a maximum drain current (I_{ON}) of 1.7×10⁻² A (drain voltage (V_{D})=−0.5 V, gate voltage (V_{G})=−0.5 V) and 4.3×10⁻³ A (V_{D}=+0.5 V, V_{G}=+0.7 V), respectively, a transconductance (gₘ) of 82.9 mS and 45.1 mS, respectively. Note, performance parameters stabilized at a dose of ˜300 μC/cm² but while without patterning the semiconducting layer similar gₘ were achieved (72.7 mS and 41.1 mS, respectively), the on/off current ratios (I_{ON/OFF}) were remarkably lower [4.1×10⁴ and 9.9×10⁶ (unpatterned) vs. 1.3×10⁶ and 1.5×10⁸ (patterned), respectively]. Thus, channel patterning substantially decreased both off-current (I_{OFF}) and the gate current (I_{G}), which are known to increase static power consumption in circuits as well as eliminates cross-talk in OECT arrays. In addition, area-normalized gₘ (g_{m,A}) and I_{ON} (I_{ON,A}) values for p- and n-type vOECTs, given by g_{m,A}=gₘ/(Wd) and I_{ON,A}=I_{ON}/(Wd), were 829 μS μm⁻² (16.7 kA cm⁻²) and 451 μS μm⁻² (4.3 kA cm⁻²), respectively. Note, the transfer characteristics of vOECTs fabricated by e-beam irradiation of the entire semiconductor film, including the channel, showed they are essentially inactive. Thus, in this vOECT architecture the semiconductor channel area is only “electronically patterned” while remaining physically connected with the e-beam exposed, and electronically-inactive, out-of-channel region.

TABLE 1
Summary of vOECT performance metrics

| | e-beam | | | | | | |
|---|---|---|---|---|---|---|---|
| | dose | I_{ON} | | V_{T} | gₘ | I_{ON, A} | g_{m, A} |
| Device | (μC/cm²) | (A) | I_{on/off} | (V) | (mS) | (kA/cm²) | (μS/μm²) |
| P-type | 0 | (1.5 ± 0.5) × 10⁻² | (4.1 ± 2.7) × 10⁴ | −0.10 ± 0.02 | 72.7 ± 23.1 | 15.1 ± 5.32 | 727 ± 231 |
| bgDPP- | 50 | (1.4 ± 0.6) × 10⁻² | (2.8 ± 1.9) × 10⁵ | −0.11 ± 0.01 | 77.9 ± 24.5 | 14.3 ± 6.07 | 779 ± 245 |
| g2T | 100 | (1.5 ± 0.3) × 10⁻² | (6.7 ± 5.7) × 10⁵ | −0.11 ± 0.03 | 82.3 ± 25.5 | 15.4 ± 3.25 | 823 ± 255 |
| vOECT | 300 | (1.7 ± 0.4) × 10⁻² | (1.3 ± 1.0) × 10⁶ | −0.13 ± 0.05 | 82.9 ± 29.1 | 16.7 ± 4.12 | 829 ± 291 |
| | 500 | (1.7 ± 0.7) × 10⁻² | (1.3 ± 1.0) × 10⁶ | −0.12 ± 0.04 | 83.4 ± 29.5 | 16.9 ± 7.38 | 834 ± 295 |
| | 1000 | (1.6 ± 0.6) × 10⁻² | (1.7 ± 1.3) × 10⁶ | −0.13 ± 0.02 | 83.8 ± 27.4 | 16.4 ± 6.02 | 838 ± 274 |
| N-type | 0 | (4.7 ± 0.9) × 10⁻³ | (9.9 ± 8.1) × 10⁶ | 0.48 ± 0.012 | 41.1 ± 13.4 | 4.7 ± 0.9 | 411 ± 134 |
| bHOMO- | 50 | (4.2 ± 1.3) × 10⁻³ | (3.7 ± 2.9) × 10⁷ | 0.49 ± 0.021 | 43.4 ± 15.7 | 4.2 ± 1.3 | 434 ± 157 |
| gDPP | 100 | (4.2 ± 0.8) × 10⁻³ | (5.5 ± 4.7) × 10⁷ | 0.44 ± 0.015 | 44.7 ± 14.9 | 4.2 ± 0.8 | 447 ± 149 |
| vOECT | 300 | (4.3 ± 1.1) × 10⁻³ | (1.5 ± 1.2) × 10⁸ | 0.45 ± 0.017 | 45.1 ± 13.4 | 4.3 ± 1.1 | 451 ± 134 |
| | 500 | (4.8 ± 1.2) × 10⁻³ | (1.6 ± 1.3) × 10⁸ | 0.46 ± 0.019 | 46.7 ± 14.5 | 4.8 ± 1.2 | 467 ± 145 |
| | 1000 | (4.4 ± 1.1) × 10⁻³ | (1.6 ± 1.3) × 10⁸ | 0.46 ± 0.023 | 47.5 ± 15.7 | 4.4 ± 1.1 | 475 ± 157 |

For all vOECT, the channel area is 10 μm×10 μm and V_{D}=−0.5 and +0.5 V for p- and n-type vOECT, respectively.
Ionic and Electronic Transport Characterization and vOECT Transient Response

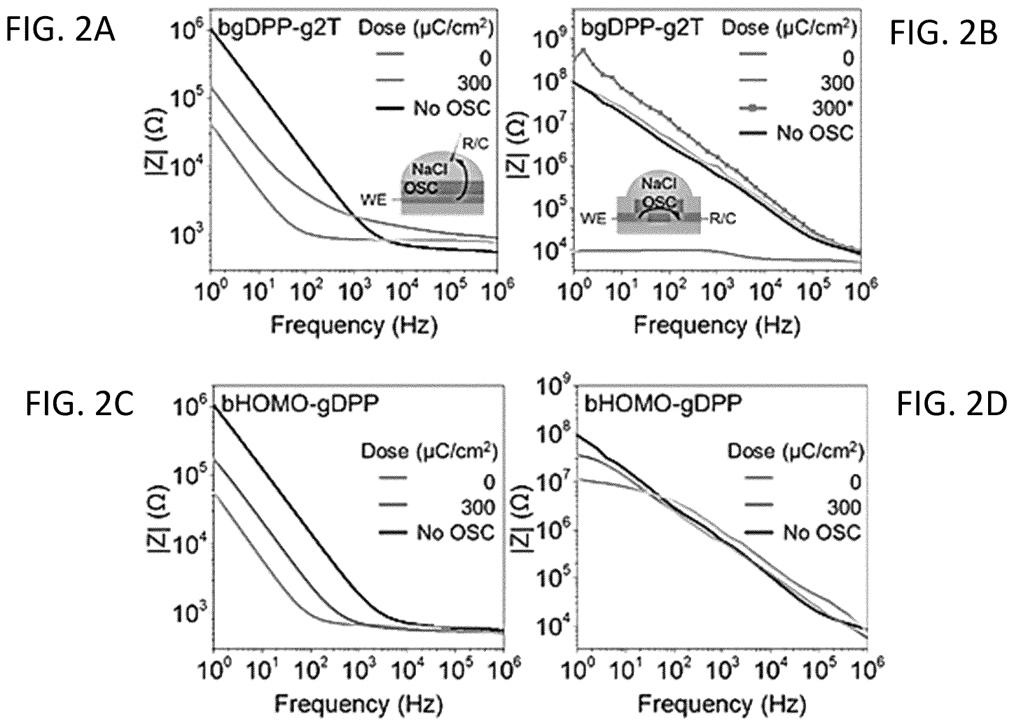

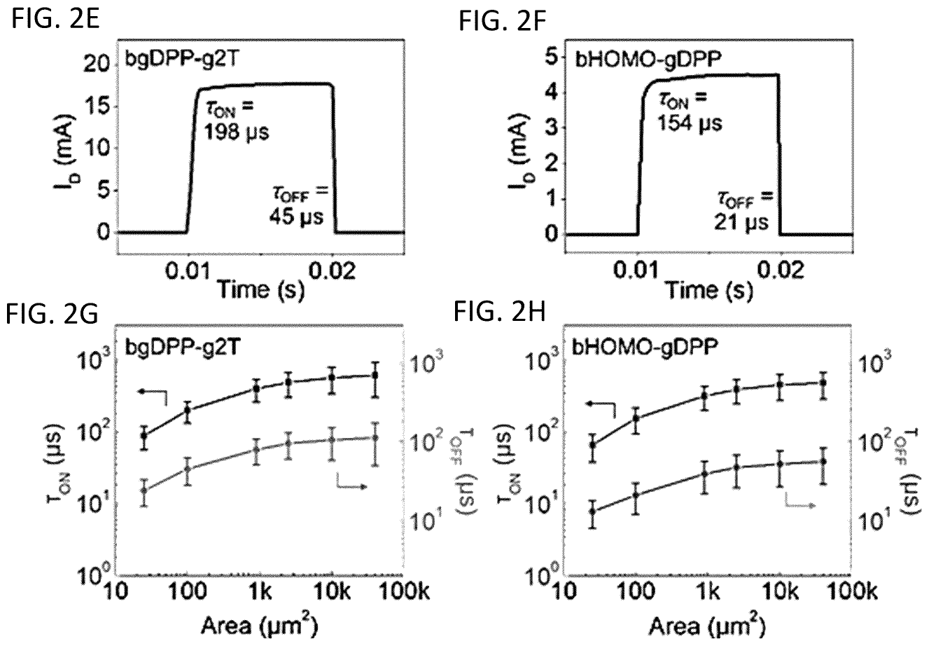

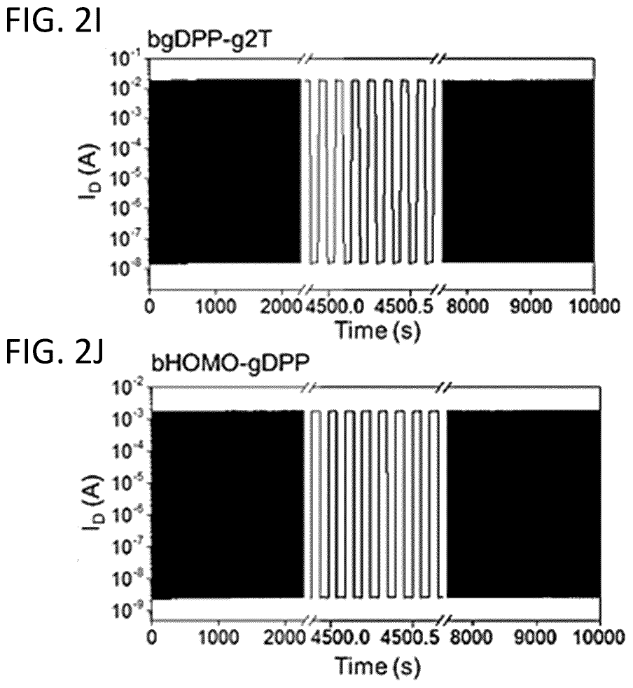

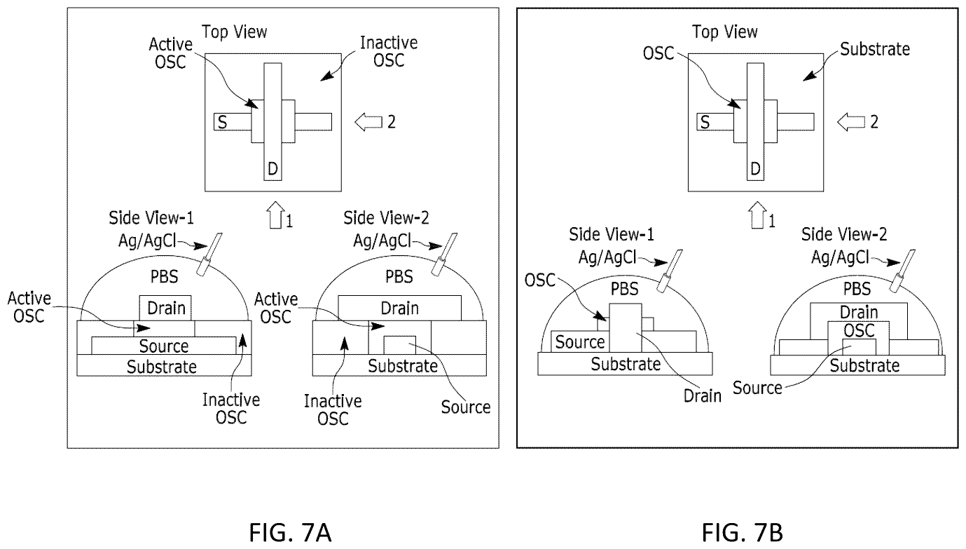

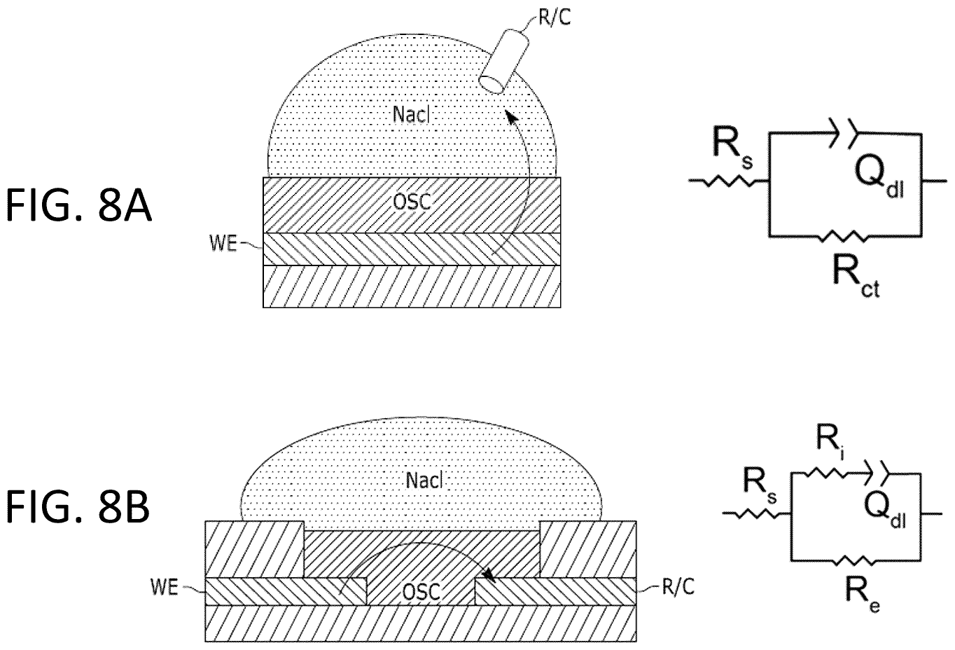

An important question is whether the e-beam exposed area remains an ionic conductor since this would also allow ions to enter the channel of the devices throughout the whole perimeter defined by the crossed electrodes (FIG. 7A), versus only two segments as in previous vOECT architectures (FIG. 7B). To validate the ionic transport in the OSC, electrochemical impedance spectroscopy (EIS) measurements were carried out for both p-/n-type semiconductor films with respect to e-beam exposure. EIS experiments were conducted in vertical and lateral configurations (FIGS. 8A-8B). (Huggins, R. A. Ionics (Kiel). 8, 300-313 (2002).) Impedance-frequency spectra of both bgDPP-g2T and bHOMO-gDPP showed a clear increase in impedance at 0.5 V and −0.7 V, respectively, confirming that electronic charge coupling is reduced by e-beam exposure (FIGS. 2A, 2C). For bgDPP-g2T, this change in material behavior was seen more obviously in the lateral EIS, where the shape of the impedance spectrum changed entirely, as seen in the large increase in impedance (FIG. 2B). Fitting this curve to an equivalent circuit, it was seen that the electronic impedance across the film increased 100,000 fold after e-beam exposure (Table 2). Fits of the ionic resistance, however, show that it remained relatively unchanged at 4.1 kΩ and 4.4 kΩ for neat and exposed samples, respectively. Due to the higher threshold voltage of the n-type, the device was “off” at 0 V prior to and after e-beam exposure. As such, it was not unexpected to see smaller differences in the spectra measured on the lateral devices, where both showed limited electronic conductivity and similar ionic conductivity (FIG. 2D and Table 2). Thus, it was confirmed that e-beam irradiation maintains the ionic conductivity of both p- and n-type organic semiconductor blends.

TABLE 2
Circuit fit values for lateral EIS configuration.

| Active | Dose | | | | | |
|---|---|---|---|---|---|---|
| Layer | (μC/cm²) | Rₛ (Ω) | Rᵢ (kΩ) | Rₑ (Ω) | Q_{dl} (nT) | n |
| No OSC | — | 2600 | 7.4 | — | 2 | 0.8 |
| bgDPP- | 0 | 2600 | 4.1 | 7.5 × 10³ | 10 | 0.9 |
| g2T | 300 | 2600 | 4.4 | 1.0 × 10⁹ | 2 | 0.8 |
| bHOMO- | 0 | 10 | 1.1 | 1.0 × 10⁷ | 4 | 0.6 |
| gDPP | 300 | 10 | 1.6 | 6.0 × 10⁶ | 9 | 0.6 |

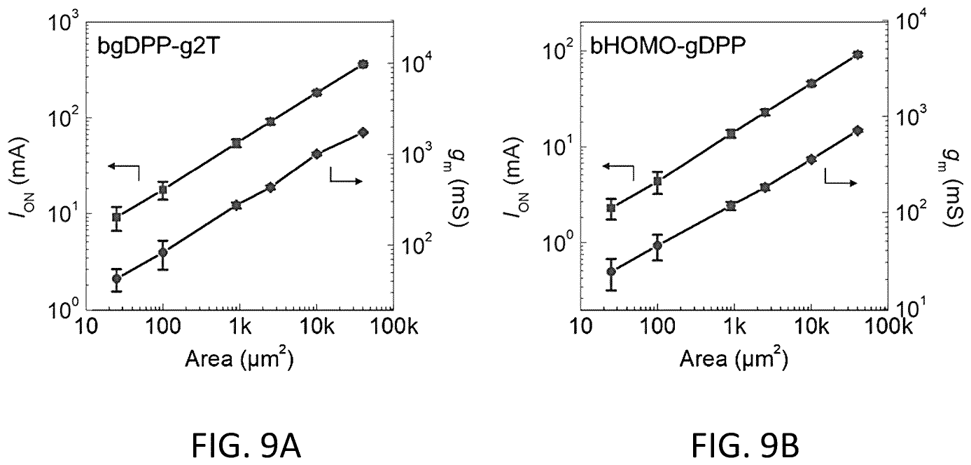

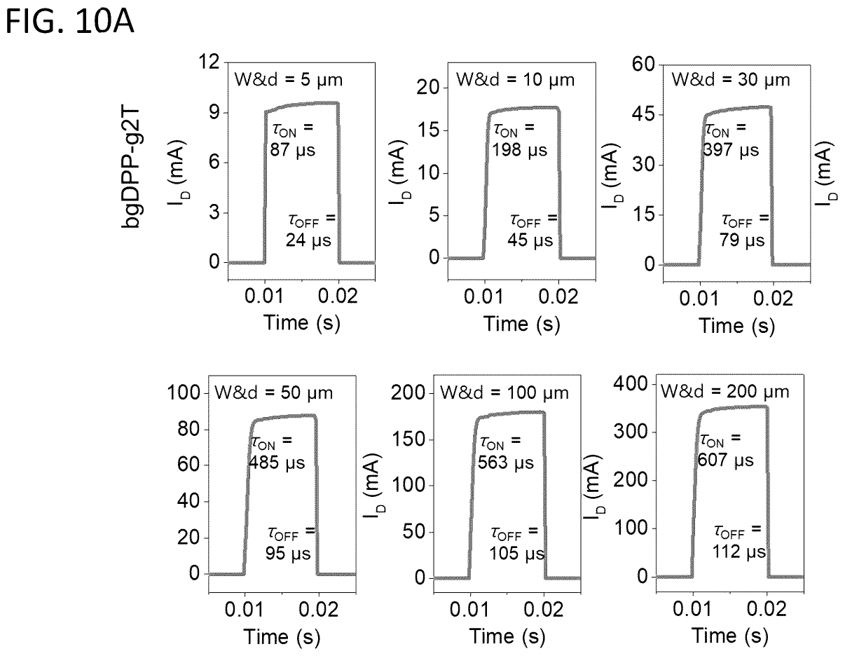

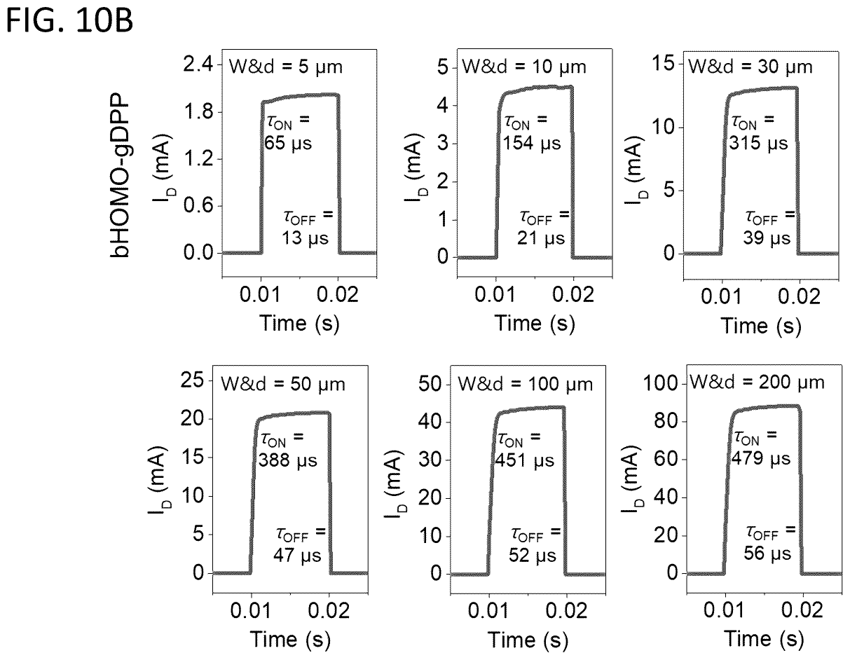

In addition, the I_{ON}, gₘ, and transient response time of the vOECTs with respect to the semiconductor channel dimension were also analysed (FIGS. 2E, 2F and FIGS. 9A-9B). It was found that I_{ON}/gₘ of both p-vOECTs and n-type vOECTs linearly increased from 9.2×10⁻³ A/42.7 mS to 3.6×10⁻¹ A/1.7 S and from 2.3×10⁻³ A/24.2 mS to 9.1×10⁻² A/0.7 S, respectively, while the turn-on (τ_{ON})/turn-off (τ_{OFF}) transient times decreased from 607/112 μs to 87/24 μs, and from 479/56 μs to 65/13 μs, respectively, as the W×d channel dimension decreased from 200×200 to 5×5 μm² (FIGS. 2G, 2H and FIGS. 10A-10B), a data in line with faster ion exchange in small devices. Furthermore, transient response characteristics were measured to demonstrate the stability for both p- and n-type vOECTs. As shown in FIGS. 2I, 2J, the vOECTs sustained more than 100 k repeated switching cycles with negligible performance degradation.

### Semiconductor Film Morphology and Spectroscopic Characterization

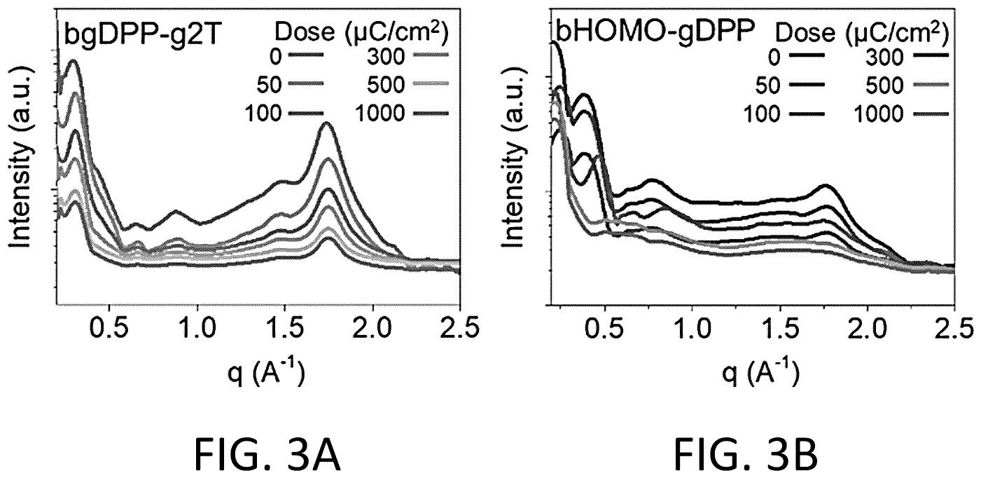

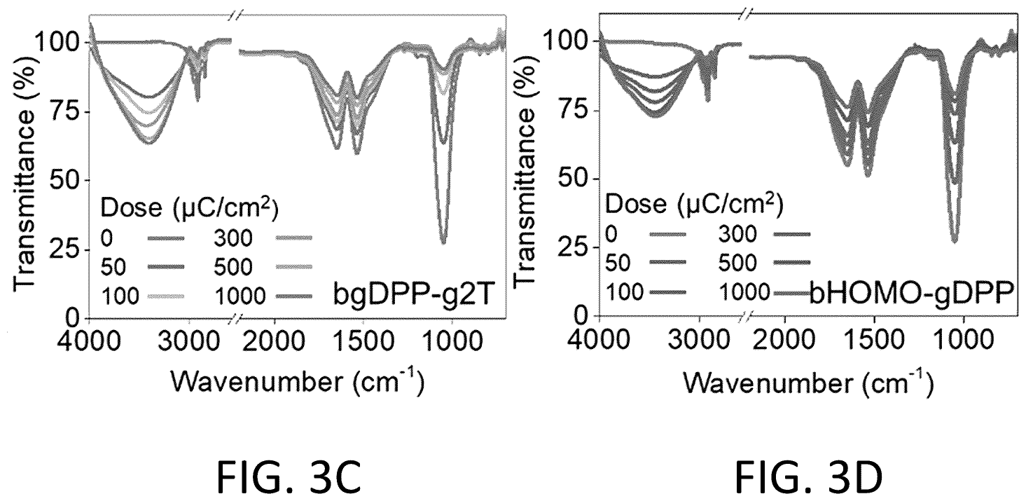

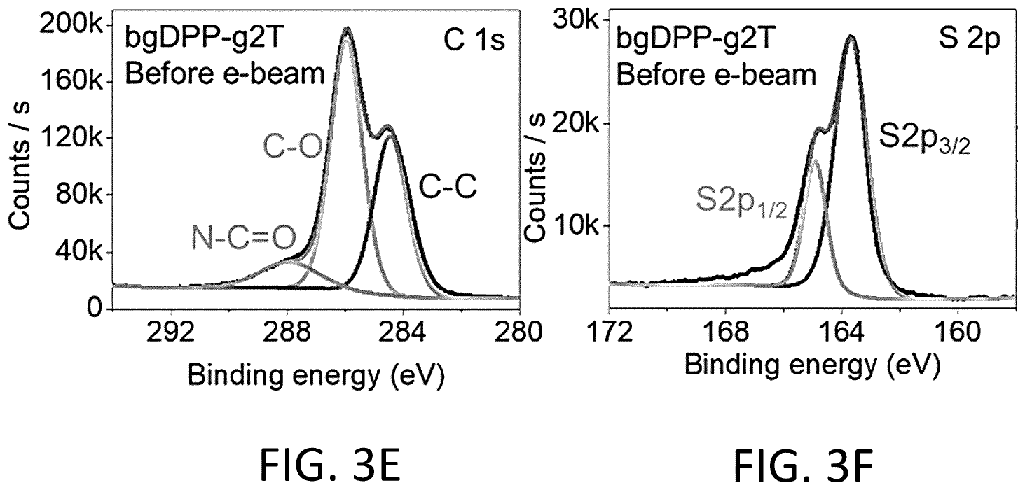

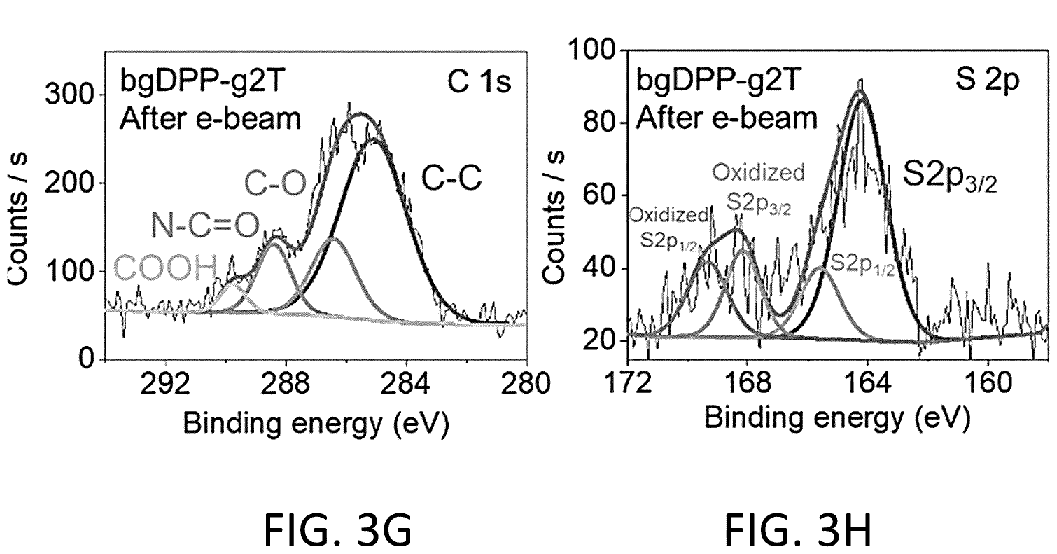

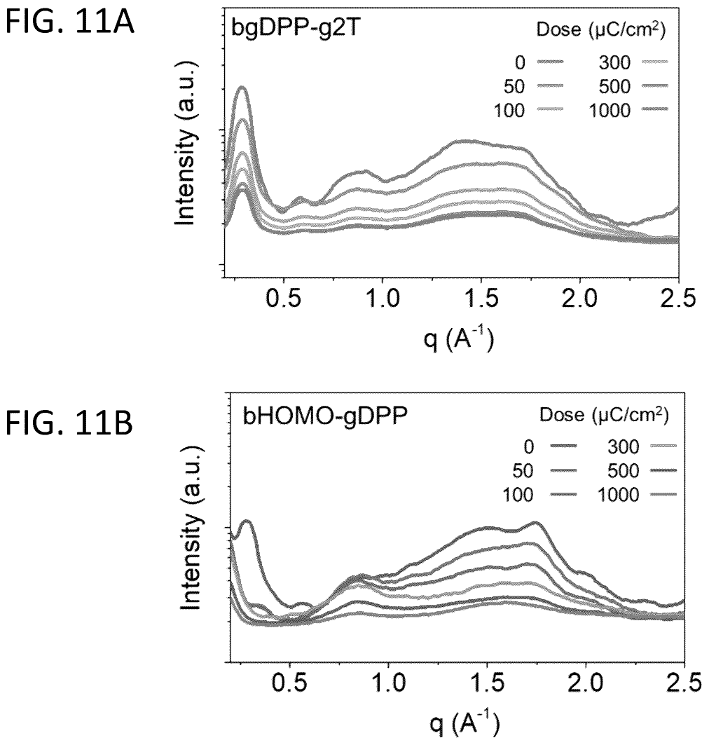

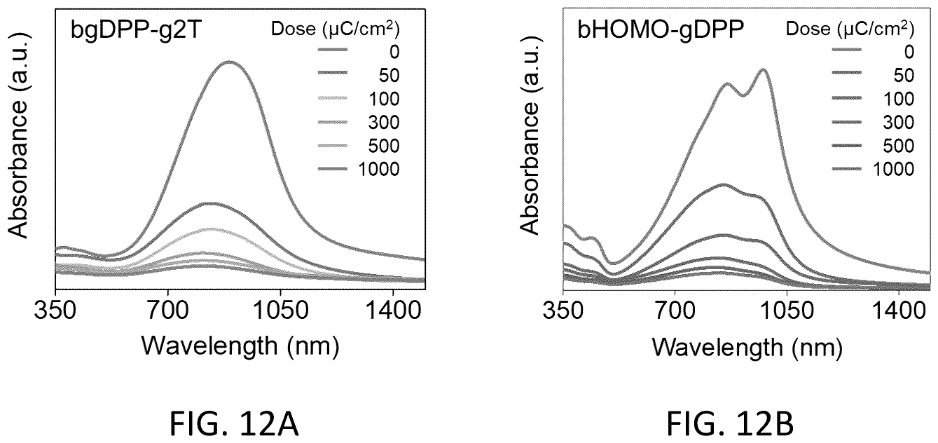

Before attempting monolithic integration, the effect of OSC e-beam exposure was investigated by multiple techniques to understand the origin of semiconductor electronic patterning. Two-dimensional grazing incidence wide-angle X-ray scattering (2D-GIWAXS) spectra of the pristine/unexposed bgDPP-g2T and bHOMO-gDPP films exhibited strong out-of-plane and in-plane reflections typical of these semicrystalline polymers (FIGS. 11A-11B). Upon e-beam exposure, the intensity of all reflections fell as the e-beam dose increased from 50 to 1000 μC/cm², as shown in the GIWAXS one-dimensional line-cuts of both polymers (FIGS. 3A-3B). Amorphization can occur via molecular reorganization and/or chemical decomposition. To address this point, Fourier transform infrared (FTIR) spectroscopy, UV-visible-near IR spectroscopy, and X-ray photoelectron spectroscopy (XPS) measurements were carried out. The FTIR spectra of the semiconductor films showed strong absorptions at 2800-3000 cm⁻¹, 1500-1700 cm⁻¹, and 1000-1200 cm⁻¹, mainly corresponding to C—H, C═C/C═O, and C—C/C—O stretching in these polymers (FIGS. 3C, 3D). The intensity of all peaks decreased upon increasing the e-beam irradiation dose while a broad peak appeared and intensified at 2800-3000 cm⁻¹ (Table 3). The latter can be assigned to O—H stretching. Interestingly, the intensity of the peaks at 1000-1200 cm⁻¹ decreased to a greater extent than those of the others indicating that most of the e-beam promoted reactions occurred at/near the C—O bond, thus in the DPP portion of the polymer. In addition, UV-visible-near infrared spectra of the polymer films indicated that the strong intramolecular charge transfer absorption band at 890 nm for bgDPP-g2T and 975 nm for Homg-gDPP decreased in intensity (−˜85% and −˜86%, respectively) and blue-shifted (811 nm and 838 nm, respectively) as the e-beam dose reached 1000 μC/cm², indicating that reactive species disrupted the polymer backbone π-conjugation (FIGS. 12A-12B and Table 4). Furthermore, XPS measurements in FIGS. 3E-3H reveal incorporation of oxygen as evidenced by formation of completely new peaks in the C 1s, S 2p and O 1s at binding energies of 289.76 eV (C(═O)—OH), 168.16 and 169.34 eV (S—O) and 535.70 eV (C(═O)—OH), respectively (Table 5). Finally, film morphology accessed by atomic force microscopy (AFM) indicated phase separation between the p-/n-polymer and the Cin-Cell additive in both pristine/e-beam exposed blends. Interestingly, the root-mean-square roughness of these films decreased from 3.1 to 2.6 nm (bgDPP-g2T) and 3.7 to 3.2 nm (bHOMO-gDPP) upon exposure, in agreement with reduced texturing of the e-beam exposed films (Table 6). Overall, the chemical and physical analysis support the claim that semiconductor film electronic patterning and amorphization mainly occur via backbone deconjugation upon uptake of oxygen as hydroxylated species and not backbone/chain fragmentation.

TABLE 3
Summary of FTIR spectra (Transmittance, %)

| | C—C | C—O | C—H | O—H |
|---|---|---|---|---|
| | (1050 | (1536, 1653 | (2848-2957 | (3450 |
| | cm⁻¹) | cm⁻¹) | cm⁻¹) | cm⁻¹) |
| bgDPP-g2T | | | | |
| Before exposure | 27.5 | 59.9, 61.9 | 79.2 | 100 |
| After exposure | 88.7 | 72.6, 73.9 | 91.9 | 70.1 |
| bHOMO-gDPP | | | | |
| Before exposure | 27.2 | 51.1, 55.0 | 78.5 | 99.3 |
| After exposure | 73.5 | 62.8, 65.7 | 88.3 | 77.9 |
| bgDPP-g2T:Cin- | | | | |
| Cell | | | | |
| Before exposure | 36.2 | 55.3, 57.7 | 80.4 | 82.4 |
| After exposure | 86.0 | 74.0, 75.3 | 91.0 | 70.2 |
| bHOMO- | | | | |
| gDPP:Cin-Cell | | | | |
| Before exposure | 28.6 | 54.1, 57.0 | 79.8 | 81.0 |
| After exposure | 70.1 | 63.4, 65.7 | 88.0 | 74.8 |
| gDPP | | | | |
| Before exposure | 59.1 | 61.7, 62.2 | 88.1 | 100 |
| After exposure | 86.5 | 80.0, 80.0 | 95.3 | 70.4 |
| gDPP:Cin-Cell | | | | |
| Before exposure | 52.2 | 62.3, 63.2 | 88.5 | 84.7 |
| After exposure | 85.5 | 78.6, 79.9 | 98.1 | 66.6 |

TABLE 4
Summary of UV-visible-near IR spectroscopy

| | Wavelength max. (nm) | Absorbance |
|---|---|---|
| bgDPP-g2T | | |
| Before exposure | 890 | 0.73 |
| After exposure | 811 | 0.12 |
| bHOMO-gDPP | | |
| Before exposure | 975 | 0.47 |
| After exposure | 838 | 0.07 |

TABLE 5
Summary of XPS
Before e-beam exposure

| bgDPP-g2T C1s | C—C | C—O | N—C═O |
|---|---|---|---|
| BE (eV) | 284.45 | 285.96 | 287.95 |
| FWHM (eV) | 1.40 | 1.34 | 2.38 |
| % Area | 35.9 | 54.3 | 9.8 |

| bgDPP-g2T N1s | N—C |
|---|---|
| BE (eV) | 399.64 |
| FWHM (eV) | 1.46 |
| % Area | 100 |

| bgDPP-g2T O1s | C═O | C—O |
|---|---|---|
| BE (eV) | 531.99 | 532.34 |
| FWHM (eV) | 3.03 | 1.43 |
| % Area | 35.9 | 64.1 |
| bgDPP-g2T S2p | S2p 3/2 | S2p 1/2 |
| BE (eV) | 163.68 | 164.92 |
| FWHM (eV) | 1.37 | 0.93 |
| % Area | 74.6 | 25.4 |

After e-beam exposure

| bgDPP-g2T C1s | C—C | C—O | N—C═O | COOH |
|---|---|---|---|---|
| BE (eV) | 285.10 | 286.42 | 288.41 | 289.76 |
| FWHM (eV) | 2.72 | 1.66 | 1.69 | 1.03 |
| % Area | 64.5 | 18.7 | 12.9 | 3.9 |

| bgDPP-g2T N1s | N—C |
|---|---|
| BE (eV) | 399.80 |
| FWHM (eV) | 2.49 |
| % Area | 100 |

| bgDPP-g2T O1s | C═O | C—O | COOH |
|---|---|---|---|
| BE (eV) | 532.03 | 533.46 | 535.70 |
| FWHM (eV) | 2.22 | 1.68 | 1.16 |
| % Area | 74.1 | 20.7 | 5.2 |

| | | | Oxidized | Oxidized |
|---|---|---|---|---|
| bgDPP-g2T S2p | S2p 3/2 | S2p 1/2 | S2p 3/2 | S2p 1/2 |
| BE (eV) | 164.20, | 165.60 | 168.16 | 169.34 |
| FWHM (eV) | 1.96, | 1.59 | 1.42 | 1.62 |
| % Area | 56.8 | 13.6 | 14.8 | 14.8 |

Before e-beam exposure

| bHOMO-gDPP C1s | C—C | C—O | N—C═O |
|---|---|---|---|
| BE (eV) | 284.20 | 285.80 | 287.60 |
| FWHM (eV) | 1.48 | 1.46 | 1.76 |
| % Area | 31.7 | 61.0 | 7.3 |

| bHOMO - gDPP N1s | N—C |
|---|---|
| BE (eV) | 399.50 |
| FWHM (eV) | 1.42 |
| % Area | 100 |

| bHOMO - gDPP O1s | C═O | C—O |
|---|---|---|
| BE (eV) | 530.30 | 532.20 |
| FWHM (eV) | 1.51 | 1.51 |
| % Area | 12.3 | 87.7 |
| bHOMO - gDPP S2p | S2p 3/2 | S2p 1/2 |
| BE (eV) | 163.68 | 164.90 |
| FWHM (eV) | 1.30 | 0.76 |
| % Area | 76.3 | 23.7 |

After e-beam exposure

| bHOMO - gDPP C1s | C—C | C—O | N—C═O | COOH |
|---|---|---|---|---|
| BE (eV) | 284.63 | 286.24 | 288.40 | 290.35 |
| FWHM (eV) | 2.32 | 1.97 | 1.53 | 1.03 |
| % Area | 54.1 | 25.4 | 16.8 | 3.8 |

| bHOMO -gDPP N1s | N—C |
|---|---|
| BE (eV) | 399.40 |
| FWHM (eV) | 3.26 |
| % Area | 100 |

| bHOMO - gDPP O1s | C═O | C—O | COOH |
|---|---|---|---|
| BE (eV) | 531.78 | 532.83 | 535.97 |
| FWHM (eV) | 2.21 | 2.56 | 1.60 |
| % Area | 53.5 | 42.2 | 4.3 |

| | | | Oxidized | Oxidized |
|---|---|---|---|---|
| bHOMO - gDPP S2p | S2p 3/2 | S2p 1/2 | S2p 3/2 | S2p 1/2 |
| BE (eV) | 163.70 | 164.89 | 167.23 | 168.75 |
| FWHM (eV) | 1.65 | 1.03 | 1.54 | 1.80 |
| % Area | 52.1 | 13.0 | 15.1 | 19.8 |

TABLE 6
Summary of AFM

| Rms (nm) | bgDPP-g2T | bHOMO-gDPP |
|---|---|---|
| Before exposure | 3.13 | 3.68 |
| After exposure | 2.59 | 3.17 |

High-Resolution vOECT Active-Matrix Arrays

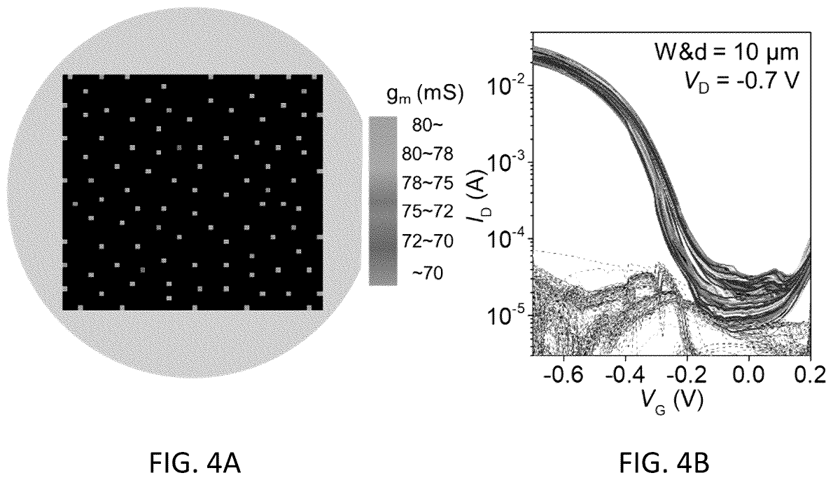

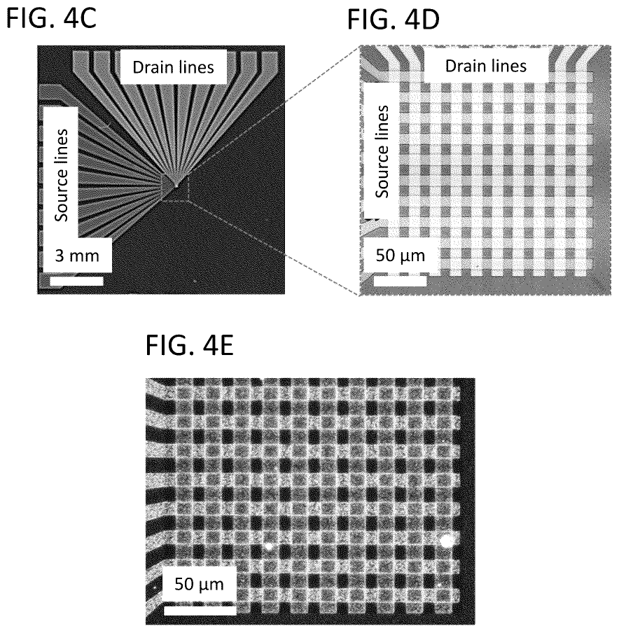

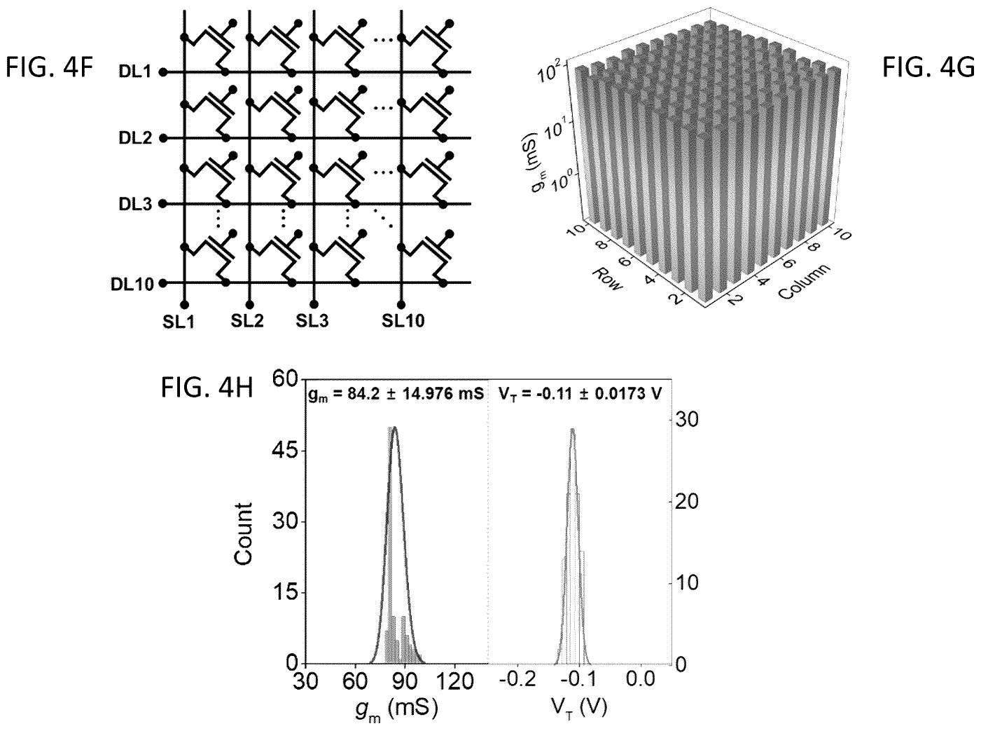

Next, vOECT active-matrix arrays of different dimensions (W=d=10 μm, metal line separation=10 μm) were fabricated to demonstrate monolithic integration with an OECT density of 3.6 M/cm², and response statistics were analyzed at both macro- and micro-scale. First, for a bgDPP-g2T (p-type) 1440×1440 vOECT array fabricated on a 2-inch wafer (>2M vOECTs), the transfer characteristics of 100 devices across the entire area were measured to assess reliability (FIGS. 4A, 4B), and outstanding device uniformity was exhibited with an average gₘ of 85.7±14.8 mS and a threshold voltage (V_{T}) of −0.11±0.03 V. Next, various batches of 10×10 p- and n-type vOECT arrays were fabricated (see optical microscope/CPOM images and equivalent circuits in FIGS. 4C-4F). All p-/n-type vOECT arrays exhibited highly uniform performance with an average gₘ of 84.2±14.9 and 43.1±9.1 mS and V_{T} of −0.11±0.02 and 0.44±0.015 V, respectively (FIGS. 4G, 4H).

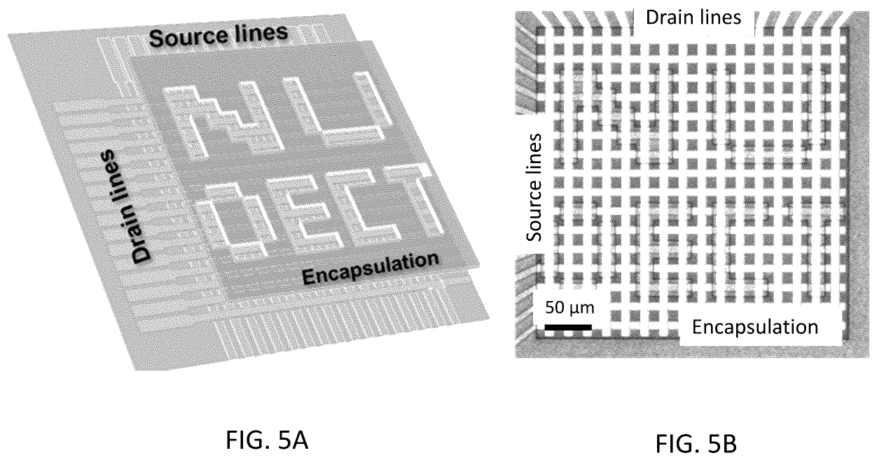

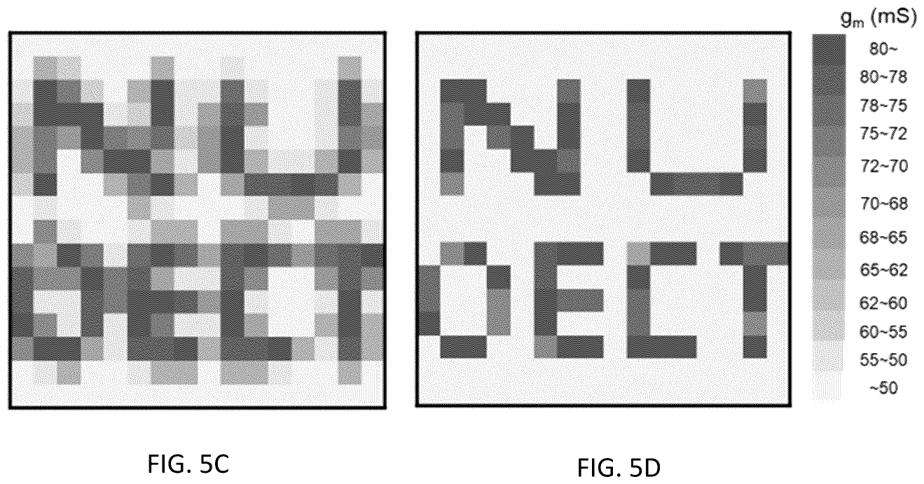

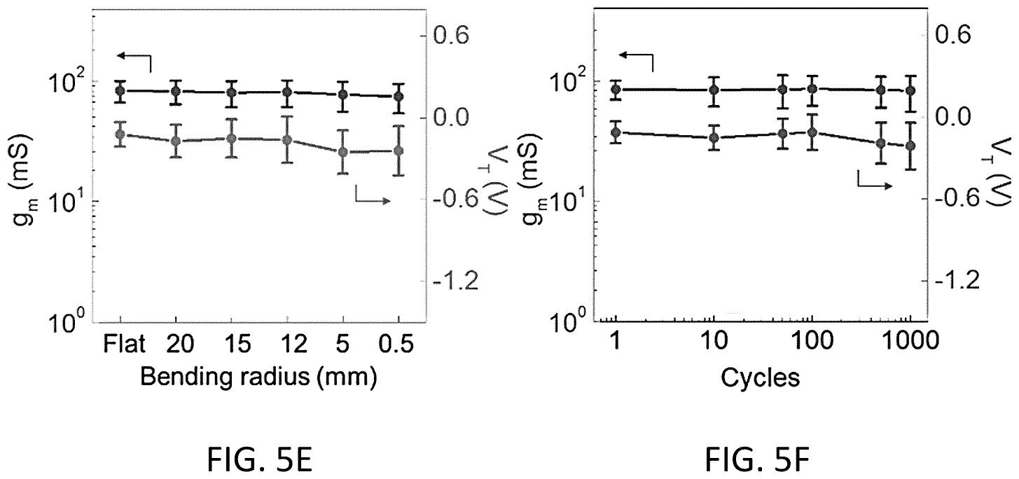

16×16 bgDPP-g2T vOECT active-matrix arrays were also fabricated, patterned by parylene encapsulation to display “NU OECT” capital letters at the center, to assess the effect of OSC patterning on pixel crosstalk (FIGS. 5A, 5B and detail in Methods). The 2D areal mapping of the array electrochemical signal (gₘ) was characterized as shown in FIG. 5C (unpatterned) and FIG. 5D (patterned), clearly demonstrating the absence of crosstalk for the patterned vOECT array. Finally, a bgDPP-g2T 10×10 vOECT array was also fabricated on a flexible parylene substrate (2 μm thick), which exhibited excellent performance metrics (gₘ=85.4±15.147 mS, V_{T}=−0.11±0.08 V) as well as outstanding stability (gₘ and V_{T} variation<2%) under various bending (from cc to 0.5 mm) and cycling (0-1000 times) mechanical deformations (FIGS. 5E, 5F).

### Vertically Stacked Complementary Logic Circuits

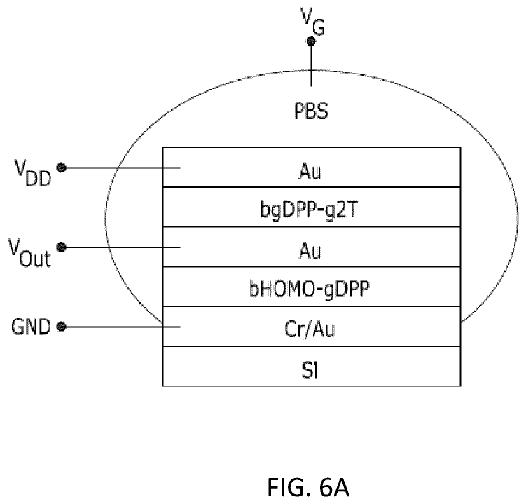

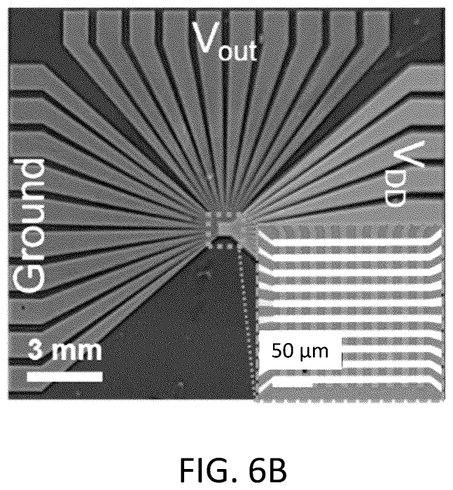

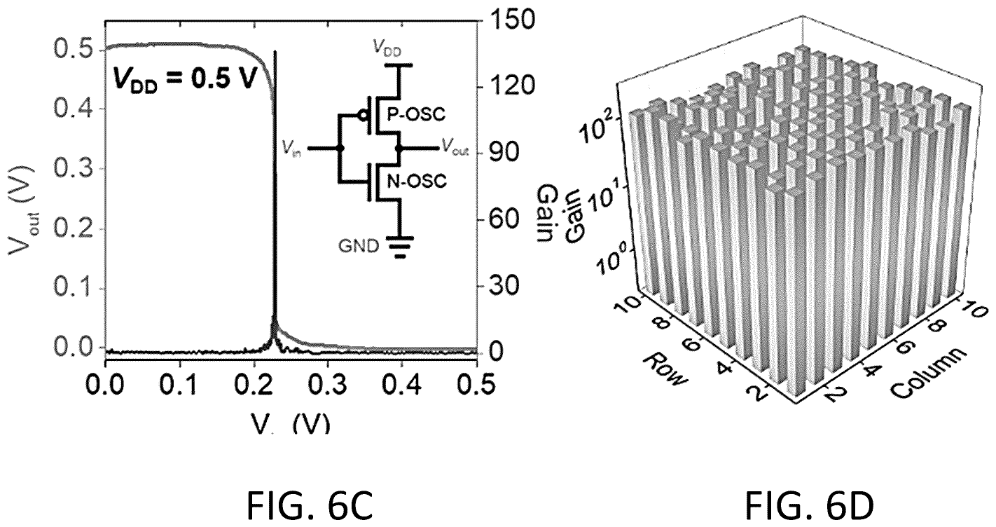

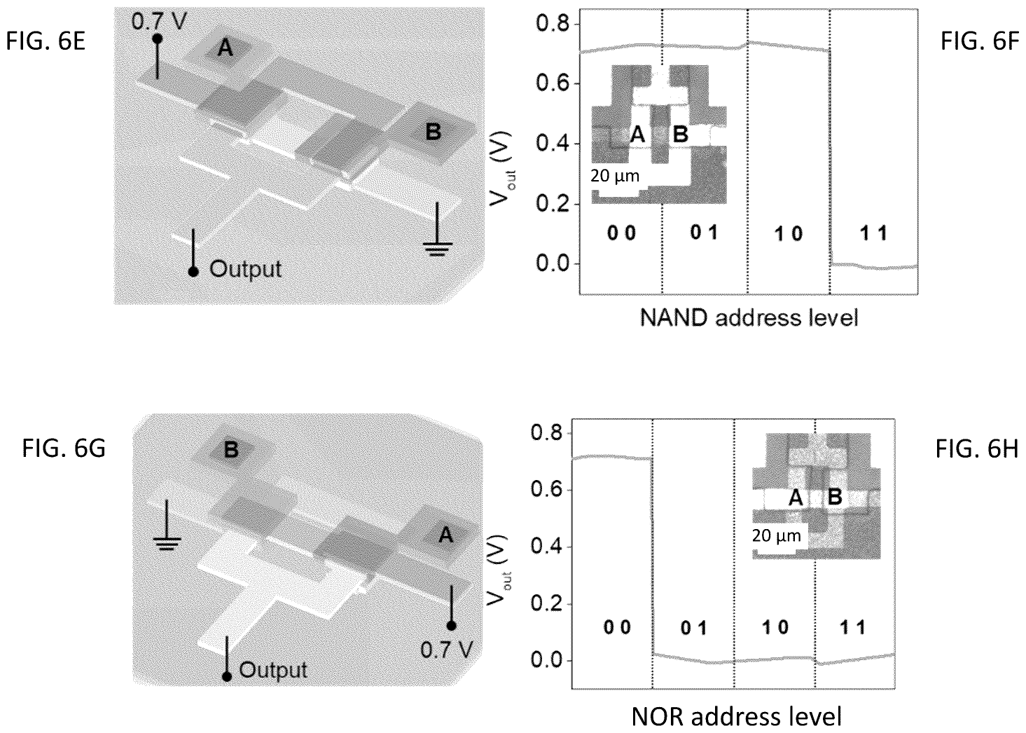

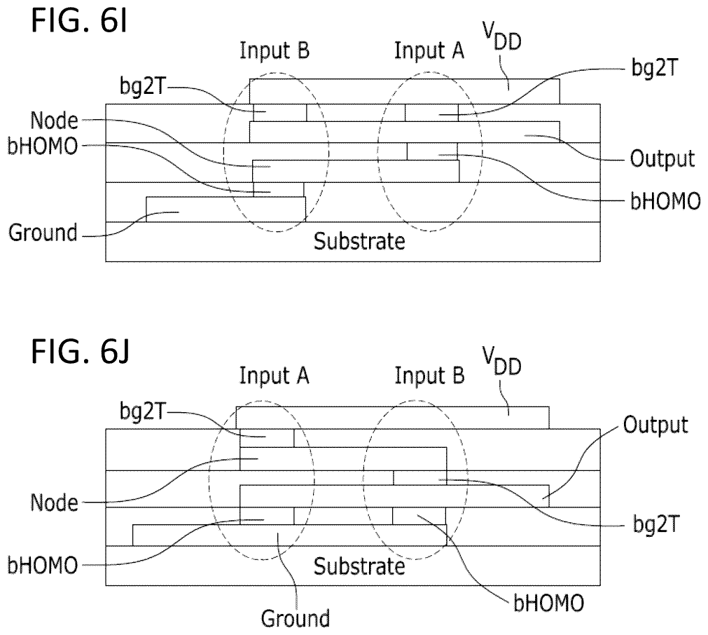

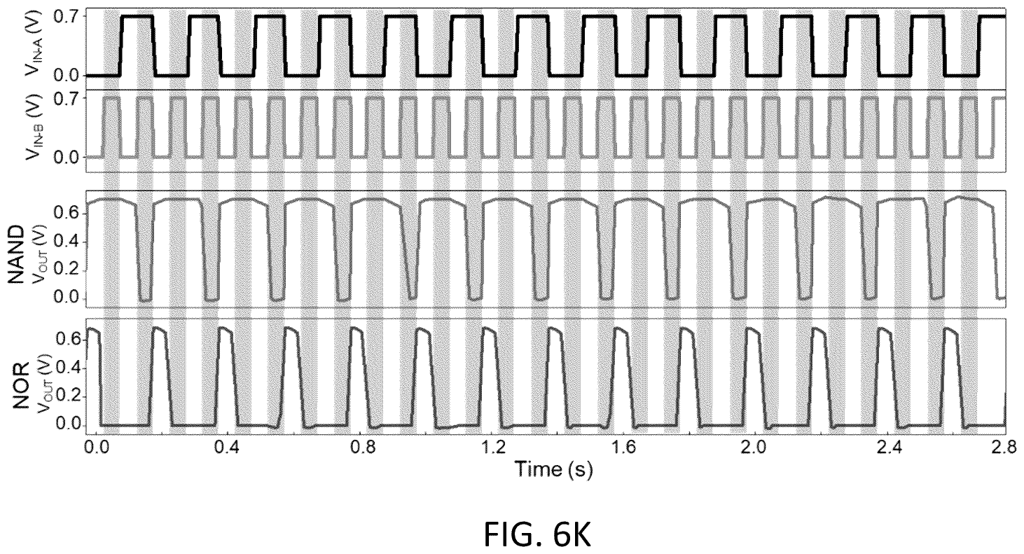

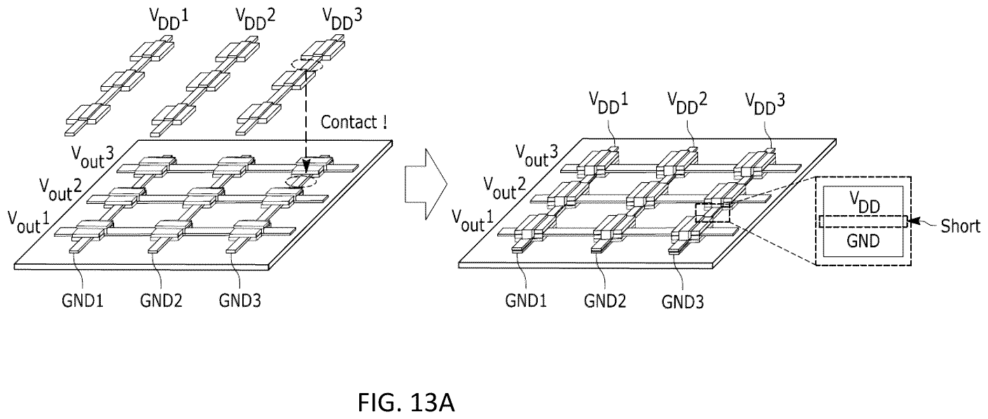

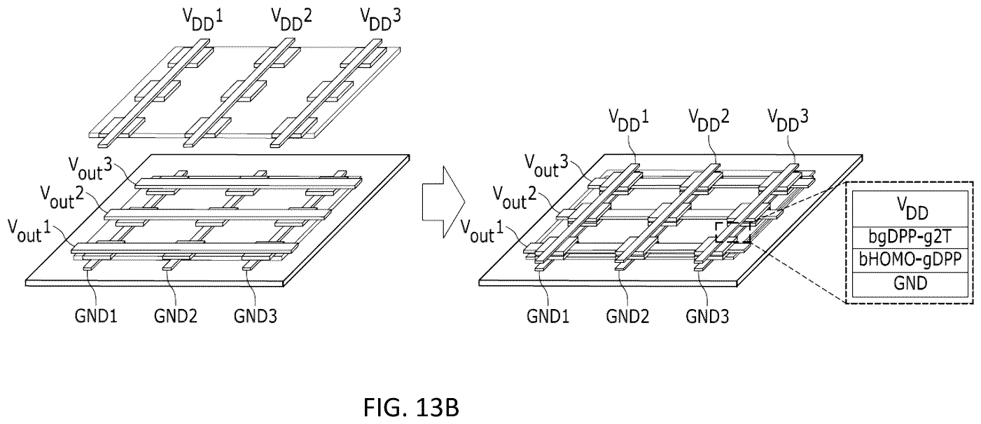

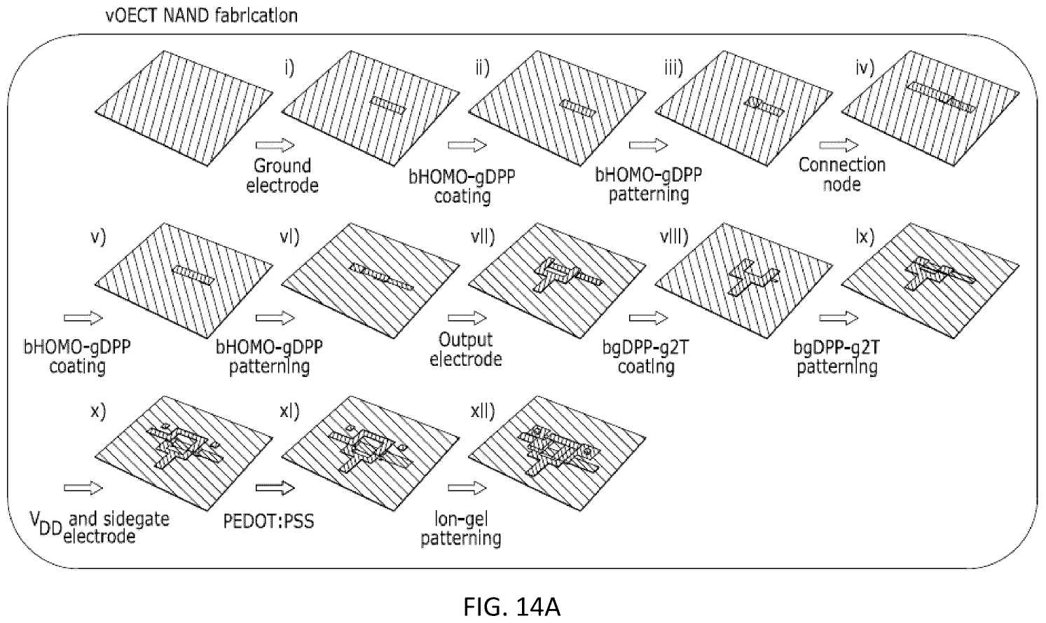

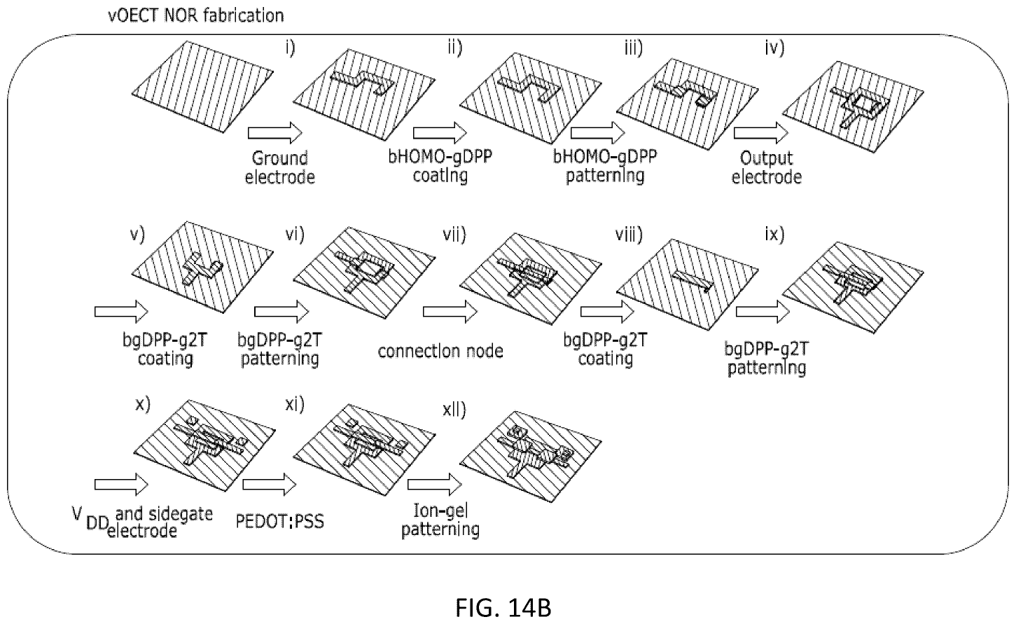

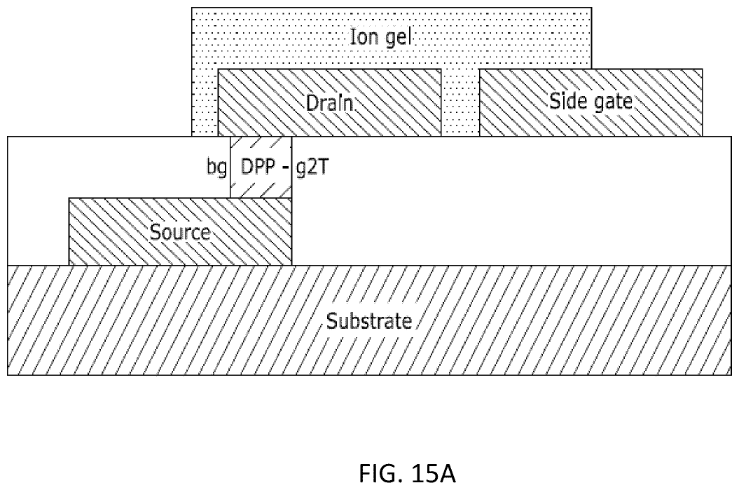

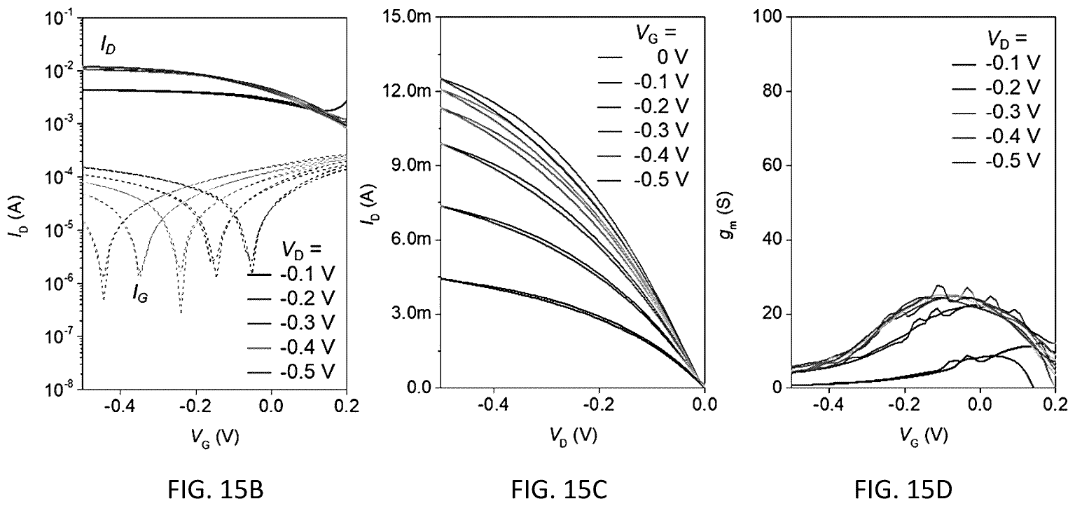

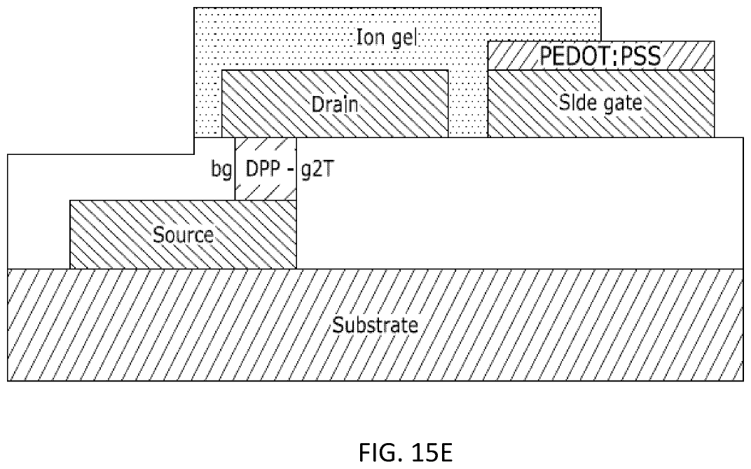

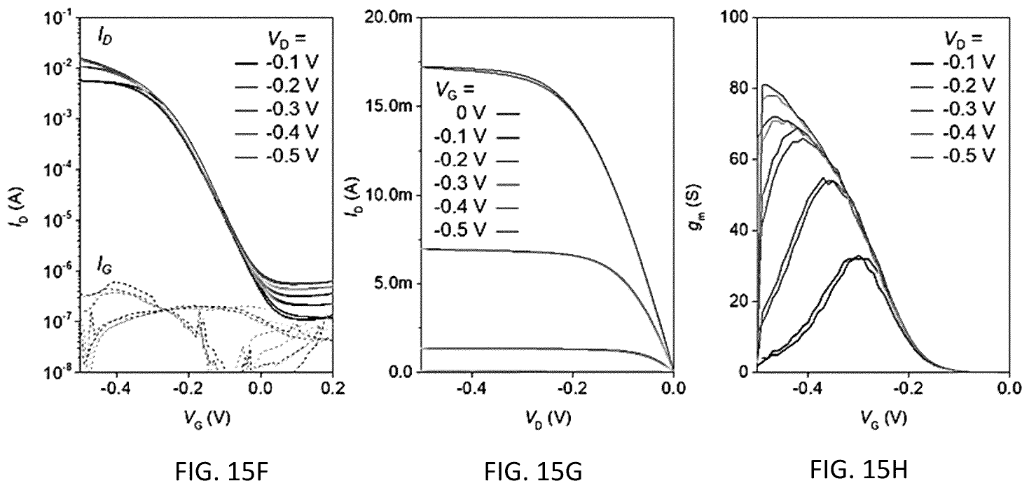

Next, high-resolution vertically stacked complementary inverter (VSCI) arrays, where p-type vOECTs were stacked on top of n-type vOECTs, were fabricated for integrated circuits. The VSCI cross-section and an optical microscope image of a 10×10 VSCI array are shown in FIGS. 6A and 6B, respectively. Note, the non-relief patterning method of the organic semiconductor using e-beam exposure can achieve a density of ˜7.2 M OECTs cm⁻². Note, in this circuit, the top and bottom electrode lines did not make an electrical contact, leading to a short circuit (FIGS. 13A-13B). A representative output characteristic of a VSCI is reported in FIG. 6C, which varied from 0.5 V to GND by changing the Input voltage from 0 to 0.5 V. This array exhibited an average voltage gain of 135.68±30.72 (FIG. 6D). The excellent performance and uniformity of the VSCI structures encouraged the realization of large-scale and high-resolution complementary circuits. Thus, two-input NAND and NOR logic gates consisting of two p- and two n-type vOECTs with a side-gate architecture and a solid-state ion-gel gate dielectric (for ion-gel solution preparation, see Methods) were demonstrated (FIG. 6E-6J and FIGS. 14A-14B). A poly(3,4-ethylenedioxythiophene):polystyrene sulfonate (PEDOT:PSS) layer/Au side-gate was employed to decrease the electrochemical impedance between the metal gate and the ion-gel dielectric layer (FIGS. 15A-15H). Using this vertically stacked complementary circuit design, the fidelity and spatial resolution of the logic circuits was significantly increased. Both circuits exhibited well-defined and highly stable “1” and “0” output logic levels depending on various input levels (FIG. 6K) and afforded a remarkable integration, with an unprecedentedly small circuit dimension of only ˜300 μm².

### Methods

### Materials Synthesis

The compounds 3,6-bis(5-bromothiophen-2-yl)-2,5-di(2,5,8,11,14-pentaoxahexadecan-16-yl)-2,5-dihydropyrrolo[3,4-c]pyrrole-1,4-dione (1), 5,5′-bis(trimethyltin)-3,3′-bis(2-(2-(2-methoxyethoxy) ethoxy)ethoxy)-2,2′-bithiophene (2), and Cin-Cell polymer were synthesized according to previously reported procedures. (Huang, W. et al. Nature 613, 496-502 (2023); Song, C. K. et al., ACS Appl. Mater. Interfaces 6, 19347-19354 (2014); Wang, Z. et al. Chem. Mater. 31, 7608-7617 (2019).) Hexabutyldistannane (3) was purchased from Sigma-Aldrich. For the synthesis of polymer bgDPP-g2T, 92.67 mg of compound 1 (0.1 mmol), 81.62 mg of compound 2 (0.1 mmol), 3.00 mg of Pd₂(dba)₃, and 7.60 mg of P(o-tol)₃ were mixed and pump-purged for three cycles with argon, and 1.5 mL of anhydrous toluene and 1.5 mL of dimethylformamide were added. The reaction vessel was next sealed and heated at 110° C. for 12 h. Then, the polymer was end-capped with 20 μl of 2-(tributylstannyl)-thiophene and 50 μl of 2-bromothiophene and heated at 110° C. for 1 h. After cooling, the mixture was mixed with 100 mL of MeOH and 1 mL of concentrated HCl. The precipitate was filtered, dried and purified by Soxhlet extraction using methanol, acetone, hexane, and then chloroform. The chloroform portion was concentrated and poured into 100 mL of MeOH. The resulting gDPP-g2T polymer was obtained by vacuum filtration as a black solid (Mn=39.7 kg/mol, yield 94%). The HOMO-gDPP polymer was synthesized using the same method with 199.00 mg of compound 1 (0.21 mmol) and 124.57 mg of compound 3 (0.21 mmol), 5.00 mg of Pd₂(dba)₃, and 13.00 mg of P(o-tol)₃ were used as starting materials. The pure HOMO-gDPP polymer was obtained as a black solid (Mn=16.4 kg/mol, yield 86%).

### Vertical OECT and Vertical Complementary Circuit Fabrication

Solution preparation. For the semiconductor solution, gDPP-g2T, HOMO-gDPP, and Cin-Cell were dissolved in chloroform (20 mg mL⁻¹ concentration) and the solutions were stirred for >8 h before use. Next these solutions were filtered through a 0.45 μm polyvinylidene difluoride filter and the gDPP-g2T or HOMO-gDPP solution was mixed with the Cin-Cell solution in a volume ratio of 9:2 before use. For the ion-gel solution, 1-ethyl-3-methylimidazolium bis(trifluoromethylsulfonyl)imide (EMIM-TFSI, Sigma-Aldrich) and poly(ethylene glycol)diacrylate (PEGDA, Sigma-Aldrich) were mixed with a volume ratio of 8:2, and 2-hydroxy-2-methyl-propiophenone (HOMPP, Sigma-Aldrich) was added to the mixture with a volume concentration of 3%. The final solution was stirred at 80° C. for 6 h.

Vertical OECT array fabrication. A Si wafer with a 300 nm thick thermally grown SiO₂ was used as the substrate, and it was cleaned by ultrasonication in acetone and next isopropyl alcohol and finally treated with an oxygen plasma for 5 min. For the flexible devices, a 2-μm-thick parylene film was used as the substrate, which was deposited on carrier glass by a parylene coater (Specialty coating system, PDS 2010, KISCO Company) via chemical vapor deposition. For the electrical contact, 3 nm of Cr and 150 nm of Au were thermally evaporated as the bottom source electrode and patterned by photolithography. Next, the semiconductor blend solution was spin-coated onto the substrate at 3,000 rpm for 20 s and the resulting film was patterned by e-beam exposure and then cross-linked by UV irradiation (65 mW/cm²) for 30 s (Inpro Technologies F300S). A 150 nm Au film was deposited by thermal evaporation as the top drain electrode and patterned by photolithography. A phosphate buffer solution (PBS, 1×) was used as the electrolyte and an Ag/AgCl electrode as the gate. When used, the encapsulation layer was prepared by spin-coating SU-8-2002 at 3,000 rpm for 20 s and the resulting film baked at 95° C. for 5 m and was patterned by photolithography.

Complementary vertical inverter array fabrication. The opposite type of semiconductor blend solution was spin-coated onto the first vOECT device/array at 3,000 rpm for 20 s, patterned by e-beam exposure and then cross-linked by UV irradiation as described above. Next, a 150 nm thick Au electrode functioning as V_{DD} was fabricated as described for the source/drain contacts. PBS (1×) and Ag/AgCl served as the electrolyte and the gate electrode/V_{IN}, respectively.

Vertical NAND fabrication. A Si/SiO₂ wafer substrate was cleaned as discussed previously. First, 3 nm of Cr and 150 nm of Au were thermally evaporated as the ground electrode and patterned by photolithography. Next, the n-type bHOMO-gDPP blend solution was spin-coated at 3,000 rpm for 20 s, patterned by e-beam exposure and then cross-linked by UV. A 150 nm Au was deposited by thermal evaporation as the node electrode and patterned by photolithography. Next, the n-type bHOMO-gDPP blend solution was spin-coated again at 3,000 rpm for 20 s, patterned by e-beam exposure and then cross-linked by UV. Then 150 nm Au was deposited by thermal evaporation as the output electrode (V_{OUT}) and patterned by photolithography. Subsequently, a p-type bgDPP-g2T blend solution was spin-coated at 3,000 rpm for 20 s, patterned by e-beam exposure and cross-linked. A 150 nm Au film was deposited by thermal evaporation as the V_{DD} and side-gate electrode and patterned by photolithography. PEDOT:PSS (Clevios PH1000, Heraeus) with 1% of 3-glycidyloxypropyl)trimethoxysilane (GOPS) solution (as a cross-linker) was spin-coated at 2,000 rpm for 20 s as the gate electrode covering Au and patterned by a lift-off process. (Kostianovskii, V. et al., Org. Electron. 44, 99-105 (2017).) Finally, the ion-gel solution was drop-cast onto the side gate device as the gate dielectric and patterned by photolithography.

Vertical NOR fabrication. The Si/SiO₂ wafer substrate, the ground electrode, and the n-type bHOMO-gDPP film were prepared as discussed above. Then 150 nm Au was deposited by thermal evaporation as the V_{OUT} electrode and patterned by photolithography. The p-type bgDPP-g2T film was then prepared as discussed above. Then 150 nm Au was deposited by thermal evaporation as the node electrode and patterned by photolithography. Finally, the p-type bgDPP-g2T film, the Au V_{DD} and side-gate electrodes, the PEDOT:PSS film and the ion-gel were prepared as discussed above.

Organic semiconductor patterning. All polymer semiconductors were patterned by e-beam exposure with a voltage of 50 kV, HC70 column mode with 18.683 nA beam current (Raith Voyager), and dose of 300 μC/cm².

### Device and Film Characterization

All OECTs, OECT arrays and circuits were characterized using an Agilent B1500A semiconductor parameter analyzer in ambient air at room temperature. The EIS measurements were conducted using a PalmSens4 potentiostat (PalmSens). For the vertical EIS, OSCs were spin-coated onto 600×600 μm Au and patterned via sacrificial parylene peel. The materials were immersed in 0.1 M NaCl and an Ag/AgCl pellet electrode was used as a gate. Bias ranges of 0.5V-0V and −0.7V-0V were applied for the p and n type respectively. For the lateral configuration, reference and counter electrodes were connected to the drain electrode of a cOECT (W=100 μm, L=10 μm), and the source was connected to the working electrode. The OSC was covered in 0.1 M NaCl and 0 V direct current (d.c.), and 10 mV alternating current (a.c.) oscillation was applied with frequency range 1 to 10⁶ Hz. For the cycling tests, the voltage pulse was generated by a Keysight waveform generator (33600A). For NAND and NOR characterization, square voltage pulses from 0 to ±0.7 V with a frequency of 5 Hz and 10 Hz were applied as V_{IN-A} and V_{IN-B}, respectively, by a Keysight waveform generator (33600A), and V_{OUT} was measured by an Agilent B1500A. Film morphologies were characterized using cross-polarized optical microscopy (ECLIPSE LV150, Nikon) and AFM (Bruker ICON System). Two-dimensional GIWAXS measurements were performed at beamline 8ID-E at the Advanced Photon Source at Argonne National Laboratory. The samples were irradiated at incidence angles from 0.130° to 0.140° in vacuum at 10.915 keV for two summed exposures of 2.5 s each. Signals were collected with a Pilatus 1M detector located at a distance of 228.16 mm from the samples. FTIR spectra were obtained in the attenuated total reflectance (ATR) mode (Broker LUMOS). UV-visible-near infrared spectra were measured with a Varian Cary 100 and Perkin Elmer LAMBDA 1050 UV-visible spectrophotometers. The XPS spectra were measured with a Thermo Scientific ESCALAB 250Xi instrument at a base pressure of 2×10⁻⁸ mbar.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.”

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. A vertical organic electrochemical transistor comprising:
a first electrode;
a second electrode;
an organic film between the first electrode and the second electrode, the organic film comprising an ionically conducting semiconductor channel region embedded in an ionically conducting electrically insulating out-of-channel region, wherein the ionically conducting semiconductor channel region forms a semiconductor channel between the first electrode and the second electrode, and further wherein the ionically conducting semiconductor channel region comprises a conjugated organic semiconductor and the ionically conducting electrically insulating out-of-channel region comprises the organic semiconductor in a partially or fully deconjugated form;
an electrolyte in contact with the organic film; and
a gate electrode in contact with the electrolyte.

2. The vertical organic electrochemical transistor of claim 1, wherein the conjugated organic semiconductor is a conjugated organic polymer semiconductor.

3. The vertical organic electrochemical transistor of claim 2, wherein the conjugated organic polymer semiconductor is an n-type conjugated organic polymer semiconductor.

4. The vertical organic electrochemical transistor of claim 3, wherein the n-type conjugated organic polymer semiconductor is a homopolymer of diketopyrrolopyrrole.

5. The vertical organic electrochemical transistor of claim 2, wherein the conjugated organic polymer semiconductor is a p-type conjugated organic polymer semiconductor.

6. The vertical organic electrochemical transistor of claim 5, wherein the p-type conjugated organic polymer semiconductor is a copolymer of diketopyrrolopyrrole and thiophene.

7. The vertical organic electrochemical transistor of claim 1, wherein the conjugated organic polymer semiconductor is a homopolymer or copolymer of isoindigo (IID), dithienothiophene (DTT), benzodithiophene (BDT), naphthalene diimide (NDI), perylene diimide (PDI), thieno[3,4-c]pyrrole-4,6-dione (TPD), bithiophene imide (BTI), benzothiadiazole (BT), indocenodithiophene (IDTT), (2,2-((2Z,2Z)-((12,13-bis(2-ethylhexyl)-3,9-diundecyl-12,13-dihydro-[1,2,5]thiadiazolo[3,4-e]thieno[2,″3:4′,5′]thieno[2′,3′:4,5]pyrrolo[3,2-g]thieno[2′,3′:4,5]thieno[3,2-b]indole-2,10-diyl)bis(methanylylidene))bis(5,6-difluoro-3-oxo-2,3-dihydro-1H-indene-2,1-diylidene))dimalononitrile) (Y6), quinoxaline (Qx) based homopolymers and copolymers, poly(3,4-ethylenedioxythiophene) polystyrene sulfonate (PEDOT:PSS), or poly(benzimidazobenzophenanthroline) (BBL).

8. The vertical organic electrochemical transistor of claim 1, further comprising photocurable organic molecules blended with the organic semiconductor.

9. The vertical organic electrochemical transistor of claim 8, wherein the photocurable organic molecules comprise at least one of a cinnamate group, a dienecinnamate group, a cumarine group, a vinyl group, an allyl group, an acrylate group, an azide group, and an oxetane group.

10. The vertical organic electrochemical transistor of claim 1, wherein the conjugated organic semiconductor is an acene, a perylene, an oligothiophene, an oligoarene, a phthalocyanine, or a heteroacene.

11. The vertical organic electrochemical transistor of claim 1, wherein the electrolyte is a liquid or a gel.

12. A vertically stacked complementary inverter comprising:
a first electrode;
a second electrode;
a first organic film between the first electrode and the second electrode, the first organic film comprising an ionically conducting semiconductor channel region embedded in an ionically conducting electrically insulating out-of-channel region, wherein the ionically conducting semiconductor channel region forms a semiconductor channel between the first electrode and the second electrode, and further wherein the ionically conducting semiconductor channel region comprises an n-type conjugated organic semiconductor and the ionically conducting electrically insulating out-of-channel region comprises the n-type organic semiconductor in a partially or fully deconjugated form;
a third electrode;
a second organic film between the second electrode and the third electrode, the second organic film comprising an ionically conducting semiconductor channel region embedded in an ionically conducting electrically insulating out-of-channel region, wherein the ionically conducting semiconductor channel region forms a semiconductor channel between the second electrode and the third electrode, and further wherein the ionically conducting semiconductor channel region comprises a p-type conjugated organic semiconductor and the ionically conducting electrically insulating out-of-channel region comprises the p-type organic semiconductor in a partially or fully deconjugated form;
an electrolyte in contact with the first organic film and the second organic film; and
a gate electrode in contact with the electrolyte.

13. The vertically stacked complementary inverter of claim 12, wherein the n-type conjugated organic semiconductor is an n-type conjugated organic polymer semiconductor and the p-type conjugated organic semiconductor is a p-type conjugated organic polymer semiconductor.

14. The vertically stacked complementary inverter of claim 13, wherein the n-type conjugated organic polymer semiconductor is a homopolymer of diketopyrrolopyrrole.

15. The vertically stacked complementary inverter of claim 14, wherein the p-type conjugated organic polymer semiconductor is a copolymer of diketopyrrolopyrrole and thiophene.

16. The vertically stacked complementary inverter of claim 12, wherein the electrolyte is a liquid or a gel.

17. A method of fabricating a vertical organic electrochemical transistor in an ionically conducting organic semiconductor film, the method comprising:
forming a first electrode on a substrate;
forming an organic film comprising an ionically conducting conjugated organic semiconductor over the first electrode;
exposing an area of the organic film to an electron-beam, the exposed area surrounding an unexposed area of the organic film, whereby the ionically conducting organic semiconductor in the exposed area of the organic film is converted into an ionically conducting electrical insulator by the deconjugation of the ionically conducting conjugated organic semiconductor;
forming a second electrode over the unexposed area of the organic film;
placing an electrolyte in contact with the organic film; and
placing a gate electrode in contact with the electrolyte.

18. The method of claim 17, wherein the ionically conducting conjugated organic semiconductor is an ionically conducting conjugated organic polymer semiconductor.

19. The method of claim 17, wherein the organic film further comprises photocurable organic molecules blended with the ionically conducting conjugated organic semiconductor.

20. The method of claim 19, further comprising exposing at least a portion of the organic film to radiation that induces crosslinking of the photocurable organic molecules to form a crosslinked organic polymer network.
